(19) United States
(12) Patent Application Publication
(10) Pub. No.: US 2025/0180646 A1
(43) Pub. Date: Jun. 5, 2025

(54) SYSTEM AND METHOD FOR TRIP COIL CURRENT SIGNATURE MONITORING

(71) Applicant: Franklin Electric Co., Inc., Fort Wayne, IN (US)

(72) Inventor: James A. Webber, Saco, ME (US)

(21) Appl. No.: 18/965,989

(22) Filed: Dec. 2, 2024

Related U.S. Application Data
(60) Provisional application No. 63/605,237, filed on Dec. 1, 2023.

(51) Int. Cl. G01R 31/327

(52) U.S. Cl. CPC G01R 31/3275

(57) ABSTRACT

An online monitor is provided including a sensor to measure current through a circuit breaker trip coil, and a processor configured to sample reference samples from the sensor during a first tripping sequence to generate a reference trip coil current signature waveform (“TCCSW”), compute a reference sample value for each reference sample, and add the reference sample values corresponding to a reference area to determine a reference area value. The processor is further configured to respond to detection of a second tripping sequence by sampling measured samples from the sensor to generate a measured TCCSW, computing a measured sample value for each measured sample, adding the measured sample values corresponding to a measured area to determine a measured area value, and determine whether a difference percentage between the reference area value and the measured area value exceeds an alarm limit.

### FIELD

The present disclosure pertains to circuit breakers, and more particularly to systems and methods for analyzing the trip coil current signature of a circuit breaker to provide information regarding the health and operational status of the circuit breaker.

### BACKGROUND

Circuit breakers, such as SF6 circuit breakers containing inert gas, are widely used in electrical substations including with one or more transformers. The circuit breakers are typically connected between the transmission lines that carry electricity from a power generation source and the transformers, which step down the voltage from the transmission lines and deliver the stepped down voltage to distribution lines that are connected to one or more electrical loads. The circuit breakers perform an important function of interrupting the current flow of electricity to prevent damage to the components downstream of the circuit breakers resulting from a short circuit or overcurrent condition upstream of the circuit breakers.

The electro-mechanical mechanisms that trip such circuit breakers in the event of a fault condition (i.e., trip coils) typically degrade over time for a variety of reasons. Utility companies are required to periodically demonstrate that the trip coils associated with the circuit breakers in their portions of the electrical grid operate in a satisfactory manner. Periodic testing of the circuit breakers is a time-consuming, expensive and potentially dangerous task. Moreover, circuit breakers that degrade and fail during the time between the periodic tests are not identified by the periodic testing. Therefore, it is desirable to provide a system and method of online, continuous monitoring, analysis and reporting of circuit breaker performance.

### SUMMARY

According to one embodiment of the present disclosure, a method is provided for identifying a fault of a circuit breaker including a trip coil assembly having a coil, the method comprising: positioning a sensor to measure current flowing through the coil; providing an online monitor to receive samples of current measured by the sensor; triggering a first tripping sequence of a circuit breaker known to operate correctly; sampling, by the online monitor, reference samples from the sensor during the first tripping sequence to generate a reference trip coil current signature waveform (“TCCSW”); computing a reference sample value for each reference sample; adding the reference sample values corresponding to a first reference area under the reference TCCSW to determine a first reference area value; monitoring, by the online monitor, operation of the circuit breaker to detect a second, subsequent tripping sequence; responding to detection of the second tripping sequence by: sampling, by the online monitor, measured samples from the sensor during the second tripping sequence to generate a measured TCCSW; computing a measured sample value for each measured sample; adding the measured sample values corresponding to a first measured area under the measured TCCSW to determine a first measured area value; computing a first difference percentage between the first reference area value and the first measured area value; and generating a first alarm in response to the first difference percentage exceeding at least one first area alarm limit. In one aspect of this embodiment, the sensor is a Hall effect sensor. In another aspect, the sampling by the online monitor is at a rate of approximately 100,000 Hertz. In yet another aspect, computing reference sample values includes, for each reference sample value, multiplying a current measured during the reference sample by a time period of the reference sample. In a variant of this aspect, computing measured sample values includes, for each measured sample value, multiplying a current measured during the measured sample by a time period of the measured sample. In a further variant, the time period of the reference sample is equal to the time period of the measured sample. In another aspect, the first reference area is a reference inrush area beginning when the first tripping sequence is triggered and ending at a first peak of the reference TCCSW and the first measured area is a measured inrush area beginning when the second tripping sequence is detected and ending at a first peak of the measured TCCSW. In another aspect, computing a first difference percentage includes computing a difference between the first reference area value and the first measured area value and dividing the difference by the first reference area value. In still another aspect, the method further comprises transmitting the first alarm via a transmitter of the online monitor to a remote device. Another aspect further comprises storing each computed reference sample value and each computed measured sample value on a memory of the online monitor. In a variant of this aspect, storing the first reference area value and the first measured area value on the memory. In another aspect of this embodiment, the method further comprises: adding the reference sample values corresponding to a second reference area under the reference TCCSW to determine a second reference area value; adding the measured sample values corresponding to a second measured area under the measured TCCSW to determine a second measured area value; computing a second difference percentage between the second reference area value and the second measured area value; and generating a second alarm in response to the second difference percentage exceeding at least one second area alarm limit. In a variant of this aspect, the second reference area is a reference latch area beginning at a first peak of the reference TCCSW and ending at a deepest valley of the reference TCCSW, and the second measured area is a measured latch area beginning at a first peak of the measured TCCSW and ending at a deepest valley of the measured TCCSW. In a further variant, the deepest valley corresponds to a plunger of the trip coil assembly reaching an end of travel. In another variant, the method further comprises: adding the reference sample values corresponding to a third reference area under the reference TCCSW to determine a third reference area value; adding the measured sample values corresponding to a third measured area under the measured TCCSW to determine a third measured area value; computing a third difference percentage between the third reference area value and the third measured area value; and generating a third alarm in response to the third difference percentage exceeding at least one third area alarm limit. In another variant, the third reference area is a reference saturation area beginning at a deepest valley of the reference TCCSW and ending at a plateau of the reference TCCSW, and the third measured area is a measured saturation area beginning at a deepest valley of the measured TCCSW and ending at a plateau of the measured TCCSW. In a further variant, the plateau corresponds to the coil being saturated with maximum current. In another variant, the method further comprises: adding the reference sample values corresponding to a fourth reference area under the reference TCCSW to determine a fourth reference area value; adding the measured sample values corresponding to a fourth measured area under the measured TCCSW to determine a fourth measured area value; computing a fourth difference percentage between the fourth reference area value and the fourth measured area value; and generating a fourth alarm in response to the fourth difference percentage exceeding at least one fourth area alarm limit. In yet a further variant, the fourth reference area is a reference buffer area beginning at a plateau of the reference TCCSW and ending at a point on the reference TCCSW corresponding to opening of a first auxiliary switch of the circuit breaker, and the fourth measured area is a measured buffer area beginning at a plateau of the measured TCCSW and ending at a point on the measured TCCSW corresponding to the opening of the first auxiliary switch. In another variant, the method further comprises: adding the reference sample values corresponding to a fifth reference area under the reference TCCSW to determine a fifth reference area value; adding the measured sample values corresponding to a fifth measured area under the measured TCCSW to determine a fifth measured area value; computing a fifth difference percentage between the fifth reference area value and the fifth measured area value; and generating a fifth alarm in response to the fifth difference percentage exceeding at least one fifth area alarm limit. In another variant, the fifth reference area is a reference discharge area beginning at the point on the reference TCCSW corresponding to opening of a first auxiliary switch and ending when the coil is deenergized, and the fifth measured area is a measured discharge area beginning at the point on the measured TCCSW corresponding to opening of the first auxiliary switch and ending when the coil is deenergized.

In another embodiment, the present disclosure provides an online monitor to identify a fault of a circuit breaker including a trip coil assembly having a coil, comprising: a sensor configured to measure current flowing through the coil; a processor in operative communication with the sensor to receive samples of current measured by the sensor; a memory including executable instructions; and a transmitter; wherein execution of the executable instructions by the processor causes the processor to: sample reference samples from the sensor during a first tripping sequence of the circuit breaker when the circuit breaker is known to operate correctly to generate a reference trip coil current signature waveform (“TCCSW”); compute a reference sample value for each reference sample; add the reference sample values corresponding to a first reference area under the reference TCCSW to determine a first reference area value; monitor operation of the circuit breaker to detect a second, subsequent tripping sequence; respond to detection of the second tripping sequence by: sampling measured samples from the sensor during the second tripping sequence to generate a measured TCCSW; computing a measured sample value for each measured sample; adding the measured sample values corresponding to a first measured area under the measured TCCSW to determine a first measured area value; compute a first difference percentage between the first reference area value and the first measured area value; and transmit, via the transmitter to a remote device, a first alarm in response to the first difference percentage exceeding at least one first area alarm limit. In one aspect of this embodiment, the sensor is a Hall effect sensor. In another aspect, the sampling by the online monitor is at a rate of approximately 100,000 Hertz. In yet another aspect, the processor computes the reference sample values by multiplying, for each reference sample value, a current measured during the reference sample by a time period of the reference sample. In a variant of this aspect, the processor computes the measured sample values by multiplying, for each measured sample value, a current measured during the measured sample by a time period of the measured sample. In another aspect, the first reference area is a reference inrush area beginning when the first tripping sequence is triggered and ending at a first peak of the reference TCCSW and the first measured area is a measured inrush area beginning when the second tripping sequence is detected and ending at a first peak of the measured TCCSW. In still another aspect, the processor computes the first difference percentage by computing a difference between the first reference area value and the first measured area value and dividing the difference by the first reference area value. In another aspect of this embodiment, execution of the executable instructions by the processor further causes the processor to store each computed reference sample value and each computed measured sample value on the memory. In a variant of this aspect, execution of the executable instructions by the processor further causes the processor to store the first reference area value and the first measured area value on the memory. In another aspect, execution of the executable instructions by the processor further causes the processor to: add the reference sample values corresponding to a second reference area under the reference TCCSW to determine a second reference area value; add the measured sample values corresponding to a second measured area under the measured TCCSW to determine a second measured area value; compute a second difference percentage between the second reference area value and the second measured area value; and transmit, via the transmitter, a second alarm in response to the second difference percentage exceeding at least one second area alarm limit. In a variant of this aspect, the second reference area is a reference latch area beginning at a first peak of the reference TCCSW and ending at a deepest valley of the reference TCCSW, and the second measured area is a measured latch area beginning at a first peak of the measured TCCSW and ending at a deepest valley of the measured TCCSW. In another variant, the deepest valley corresponds to a plunger of the trip coil assembly reaching an end of travel. In another variant, execution of the executable instructions by the processor further causes the processor to: add the reference sample values corresponding to a third reference area under the reference TCCSW to determine a third reference area value; add the measured sample values corresponding to a third measured area under the measured TCCSW to determine a third measured area value; compute a third difference percentage between the third reference area value and the third measured area value; and transmit, via the transmitter, a third alarm in response to the third difference percentage exceeding at least one third area alarm limit. In a further variant, the third reference area is a reference saturation area beginning at a deepest valley of the reference TCCSW and ending at a plateau of the reference TCCSW, and the third measured area is a measured saturation area beginning at a deepest valley of the measured TCCSW and ending at a plateau of the measured TCCSW. In another variant, the plateau corresponds to the coil being saturated with maximum current. In another variant, execution of the executable instructions by the processor further causes the processor to: add the reference sample values corresponding to a fourth reference area under the reference TCCSW to determine a fourth reference area value; add the measured sample values corresponding to a fourth measured area under the measured TCCSW to determine a fourth measured area value; compute a third difference percentage between the fourth reference area value and the fourth measured area value; and transmit, via the transmitter, a fourth alarm in response to the fourth difference percentage exceeding at least one fourth area alarm limit. In a further variant, the fourth reference area is a reference buffer area beginning at a plateau of the reference TCCSW and ending at a point on the reference TCCSW corresponding to opening of a first auxiliary switch of the circuit breaker, and the fourth measured area is a measured buffer area beginning at a plateau of the measured TCCSW and ending at a point on the measured TCCSW corresponding to opening of the first auxiliary switch. In another variant, execution of the executable instructions by the processor further causes the processor to: add the reference sample values corresponding to a fifth reference area under the reference TCCSW to determine a fifth reference area value; add the measured sample values corresponding to a fifth measured area under the measured TCCSW to determine a fifth measured area value; compute a fourth difference percentage between the fifth reference area value and the fifth measured area value; and transmit, via the transmitter, a fifth alarm in response to the fifth difference percentage exceeding at least one fifth area alarm limit. In a still further variant, the fifth reference area is a reference discharge area beginning at the point on the reference TCCSW corresponding to the opening of the first auxiliary switch and ending when the coil is deenergized, and the fifth measured area is a measured discharge area beginning at the point on the measured TCCSW corresponding to the opening of the first auxiliary switch and ending when the coil is deenergized.

In yet another embodiment, the present disclosure provides an online monitor to identify a fault of a circuit breaker including a trip coil assembly having a coil, comprising: a sensor configured to measure current flowing through the coil; and a processor in operative communication with the sensor to receive samples of current measured by the sensor; wherein the processor is configured to: sample reference samples from the sensor during a first tripping sequence of the circuit breaker when the circuit breaker is known to operate correctly to generate a reference trip coil current signature waveform (“TCCSW”); compute a reference sample value for each reference sample; add the reference sample values corresponding to a first reference area under the reference TCCSW to determine a first reference area value; respond to detection of a second, subsequent tripping sequence by: sampling measured samples from the sensor during the second tripping sequence to generate a measured TCCSW; computing a measured sample value for each measured sample; adding the measured sample values corresponding to a first measured area under the measured TCCSW to determine a first measured area value; and determine whether a first difference percentage between the first reference area value and the first measured area value exceeds at least one first area alarm limit.

### BRIEF DESCRIPTION OF THE DRAWINGS

The above-mentioned and other advantages and objects of this disclosure, and the manner of attaining them, will become more apparent, and the disclosure itself will be better understood, by reference to the following description of embodiments of the invention taken in conjunction with the accompanying drawings, wherein:

FIG. 1 is a conceptual diagram of a circuit breaker as configured during normal operation;

FIG. 2A is a simplified conceptual diagram of a circuit breaker as configured during normal operation;

FIGS. 2B through 2G are conceptual diagrams of the circuit breaker of FIG. 2A in various stages of a tripping sequence;

FIG. 3 is a conceptual diagram of a circuit breaker and an online monitoring system according to one embodiment of the present disclosure;

FIG. 4 is a graph depicting a reference trip coil current signature waveform and a measured trip coil current signature waveform as monitored by the monitoring system of FIG. 3;

FIGS. 5A through 5J are graphs depicting segments or areas of the reference and measured trip coil current signature waveforms depicted in FIG. 4;

FIG. 6 is a graph depicting a reference trip coil current signature waveform;

FIG. 7 depicts a comparison between a latch area of a reference trip coil current signature waveform and a latch area of a measured trip coil current signature waveform;

FIG. 8 depicts a comparison between a buffer area of a reference trip coil current signature waveform and a buffer area of a measured trip coil current signature waveform;

FIG. 9 depicts a comparison between a reference trip coil current signature waveform and a measured trip coil current signature waveform indicating a slow latch assembly;

FIG. 10 depicts a comparison between a reference trip coil current signature waveform and a measured trip coil current signature waveform indicating a slow coil saturation;

FIG. 11 is a graph illustrating a computation of an overall value of an area under a portion of the measured trip coil current signature waveform depicted in FIG. 4;

FIG. 12 is a flow chart of a method for establishing reference values for various areas from the reference trip coil current signature waveform depicted in FIG. 4;

FIGS. 13 and 14 are flow charts of a method for collecting and analyzing the measured trip coil current signature waveform depicted in FIG. 4;

FIG. 15 is a graph depicting a low battery supply voltage; and

FIG. 16 is a graph depicting a measured trip coil current signature waveform when there are loose connections in the control circuit.

Corresponding reference characters indicate corresponding parts throughout the several views. Although the drawings represent embodiments of the present disclosure, the drawings are not necessarily to scale, and certain features may be exaggerated or omitted in some of the drawings in order to better illustrate and explain the present disclosure.

### DETAILED DESCRIPTION

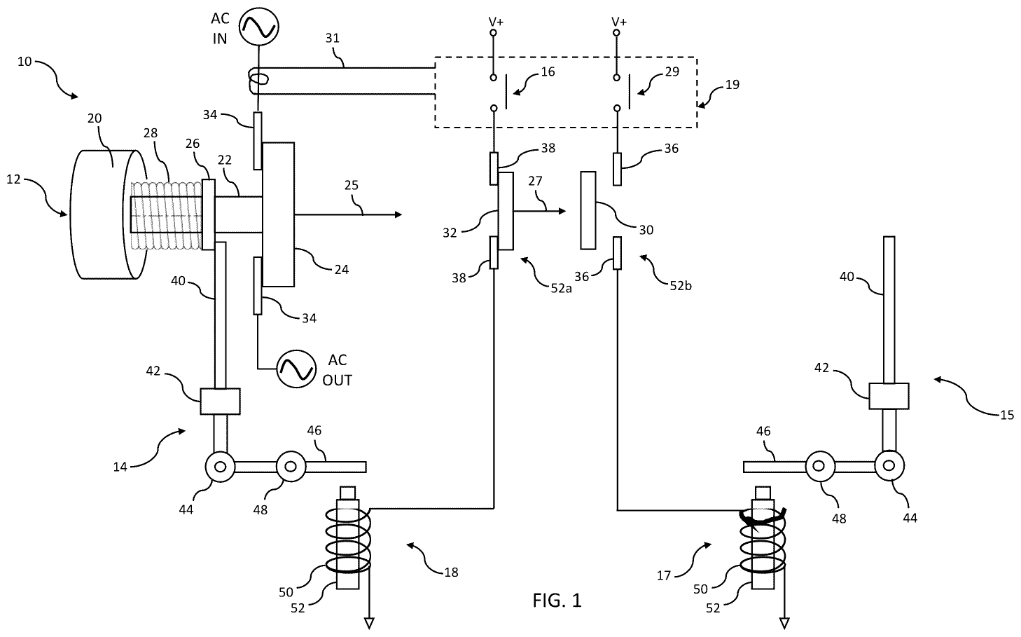

Referring now to FIG. 1, a circuit breaker 10 is shown in a normal operating configuration. The circuit breaker 10 generally includes a main contact assembly 12, a trip latch assembly 14, a trip coil assembly 18, a close latch assembly 15, a close coil assembly 17, a protective relay 19, a first auxiliary switch 52a and a second auxiliary switch 52b. Three main contact assemblies 12 are used (only one shown), one for each phase of the AC input power. Each main contact assembly 12 includes a base 20 which receives a portion of an arm 22 of the main contact conductor 24. A shoulder 26 is formed on the arm 22. A spring 28 is compressed between the base 20 and the shoulder 26 when the trip latch assembly 14 is in the normal operating configuration as shown in FIG. 1. The auxiliary switches 52a and 52b are mechanically coupled to the main contact conductor 24 via mechanical linkages 25 and 27. When the circuit breaker 10 is in the normal operating configuration, the main contact conductor 24 completes a connection between the main contacts 34 and the contact 32 of the first auxiliary switch 52a completes a connection between the auxiliary contacts 38. The contact 30 of the second auxiliary switch 52b is normally opened (i.e., does not make contact with the auxiliary contacts 36) when the circuit breaker 10 is in the normal operating configuration. As is further described below, the second auxiliary switch 52b closes when the circuit breaker 10 is tripped.

The protective relay 19 includes a trip contact 16 which is normally opened such that DC voltage (V+) is not provided through the trip contact 16 to the first auxiliary switch 52a and the trip coil assembly 18. The protective relay 19 also includes a close contact 29 which is also normally opened such that V+ is not provided through the close contact 29 to the second auxiliary switch 52b and the close coil assembly 17. In certain embodiments, V+ is supplied by a 125 volt battery bank located in a control building. The protective relay 19 includes a current sensor 31 which is configured to measure current provided by the AC input power line to the main contact assembly 12. As is further described below, a high current condition (i.e., a fault) on the AC input power line causes the circuit breaker 10 to trip.

The trip latch assembly 14 includes a retaining arm 40 that is configured to move within a stationary guide 42. When in the normal operating configuration shown in FIG. 1, the free end of the retaining arm 40 overlaps the shoulder 26 of the arm 22 of the main contact assembly 12 to prevent the spring 28 from causing the arm 22 to move away from the base 20 (i.e., to the right in FIG. 1). The other end of the retaining arm 40 is pivotally connected to a hinge or pivot assembly 44, which is also connected to an actuator arm 46 of the latch assembly 14. The actuator arm 46 is configured to pivot about a pivot assembly 48 as is further described below.

The trip coil assembly 18 includes a coil 50 that produces a magnetic field when electricity runs through the coil 50. The magnetic field interacts with a plunger 52 of the trip coil assembly 18, moving the plunger 52 upwardly as viewed in FIG. 1. As shown, one end of the coil 50 is connected to ground and the other end is connected to the contact 38 of the first auxiliary switch 52a.

The close coil assembly 17 and the close latch assembly 15 are the same as the trip coil assembly 18 and the trip latch assembly 14, respectively. The coil 50 of the close coil assembly 17 is connected between the contact 36 of the second auxiliary switch 52b and ground.

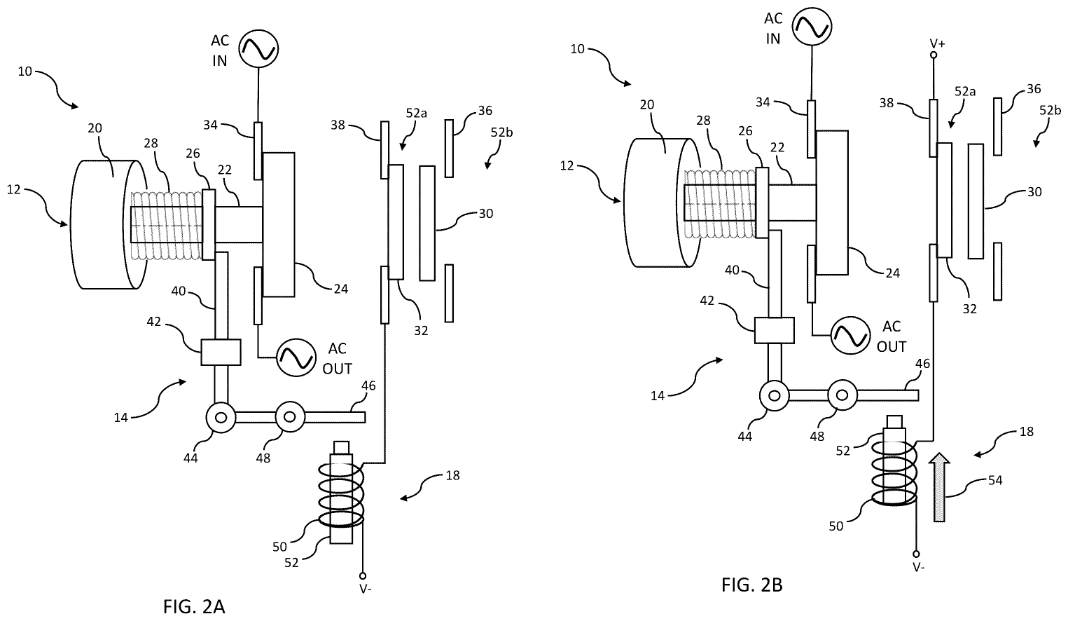

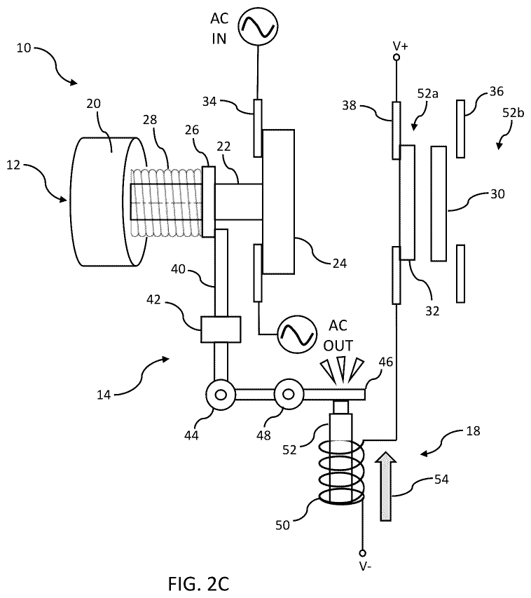

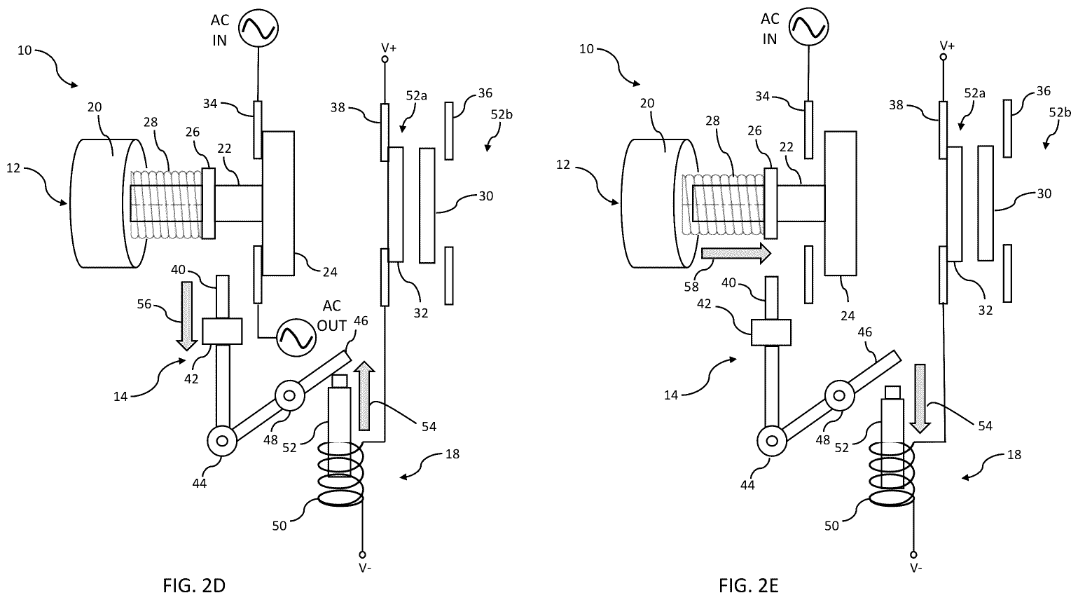

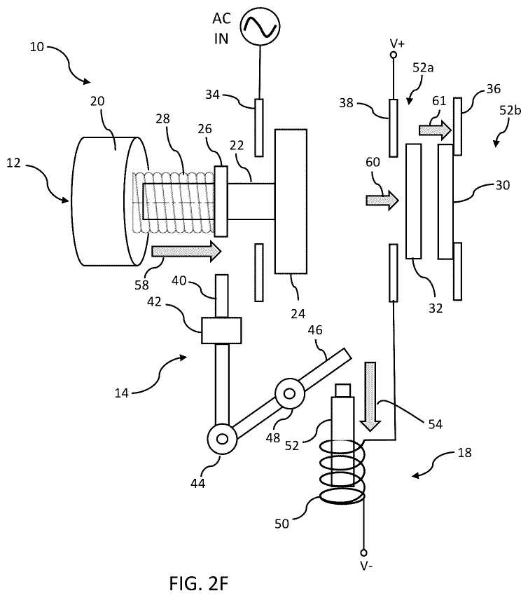

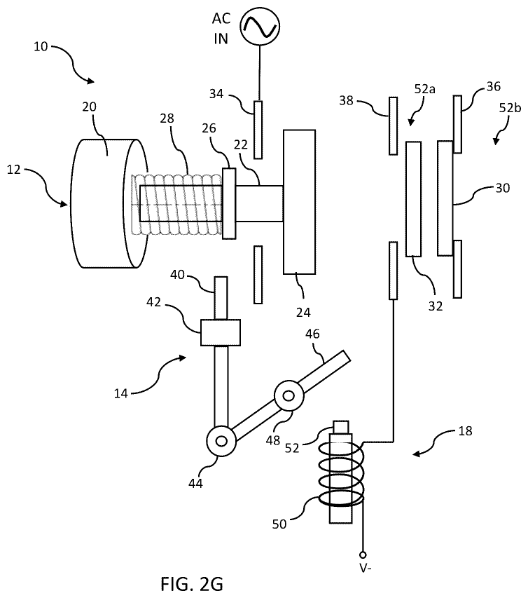

FIGS. 2A through 2G are simplified versions of FIG. 1 which omit the close latch assembly 15, the close coil assembly 17 and the close contact 29 of the protective relay 19. In the normal operating configuration depicted in FIG. 2A, current flows through the main contacts 34 to the load(s) connected to the circuit breaker 10. V+ is not provided to the first auxiliary switch 52a because the trip contact 16 (FIG. 1) is opened until a fault is detected by the current sensor 31. When a fault occurs, such as when a limb of a tree causes a short circuit on the transmission lines connected to the circuit breaker 10, the circuit breaker 10 begins the trip sequence depicted in FIGS. 2B through 2G.

Referring to FIG. 2B, when a fault occurs, the trip contact 16 is moved from its opened position (shown in FIG. 1) to its closed position in response to the current sensor 31 measuring current on the AC input line that exceeds a programmable threshold. Thus, the V+ voltage is provided to the first auxiliary switch 52a (which is normally closed) and current begins to flow through the coil 50 of the trip coil assembly 18, which generates a magnetic field that causes the plunger 52 to move upwardly as indicated by the arrow 54. AC output power is still provided to the load(s) of the circuit breaker 10 as the main contact assembly 12 has not opened.

Referring now to FIG. 2C, the plunger 52 is shown at the moment of contact with the actuator arm 46 of the trip latch assembly 14. As the plunger 52 continues to move upwardly, as shown in FIG. 2D, it causes the actuator arm 46 to pivot about the pivot assembly 48, which in turn causes the retaining arm 40 (through the pivot assembly 44) to move downwardly through the stationary guide 42 as indicated by the arrow 56. Consequently, the retaining arm 40 moves out of contact with the shoulder 26 of the arm 22 of the main contact assembly 12. As shown in FIG. 2E, after the retaining arm 40 moves out of contact with the shoulder 26, the arm 22 of the main contact assembly 12 is permitted to move away from the base 20 under the biasing force of the spring 28 as indicated by the arrow 58. This movement causes the main contact conductor 24 to move away from and out of contact with the main contacts 34, thereby preventing further current flow through the main contacts 34 to the load(s).

As shown in FIG. 2F, this movement of the main contact assembly 12 also causes the contact 32 of the first auxiliary switch 52a to move via the linkage 25 (FIG. 1) out of contact with the auxiliary contacts 38 as indicated by arrow 60, which begins to deenergize the coil 50. The movement also causes the contact 30 of the second auxiliary switch 52b to move via linkage 27 (FIG. 1) into contact with the auxiliary contacts 36 as indicated by arrow 61. Once the coil 50 of the latch coil assembly 18 begins to deenergize, the plunger 50 begins to move downwardly as indicated by arrow 54.

FIG. 2G depicts the circuit breaker 10 after the tripping sequence is complete when the trip contact 16 is opened and the coil 50 is deenergized. The arm 22 of the main contact assembly 12 is fully extended by the biasing force of the spring 28 and the main contact conductor 24 is disconnected from the main contacts 34. The contact 32 of the first auxiliary switch 52a is also disconnected from the auxiliary contacts 38, the contact 30 of the second auxiliary switch 52b is connected to the auxiliary contacts 36, and the plunger 52 of the trip coil assembly 18 has returned to its fully retracted position.

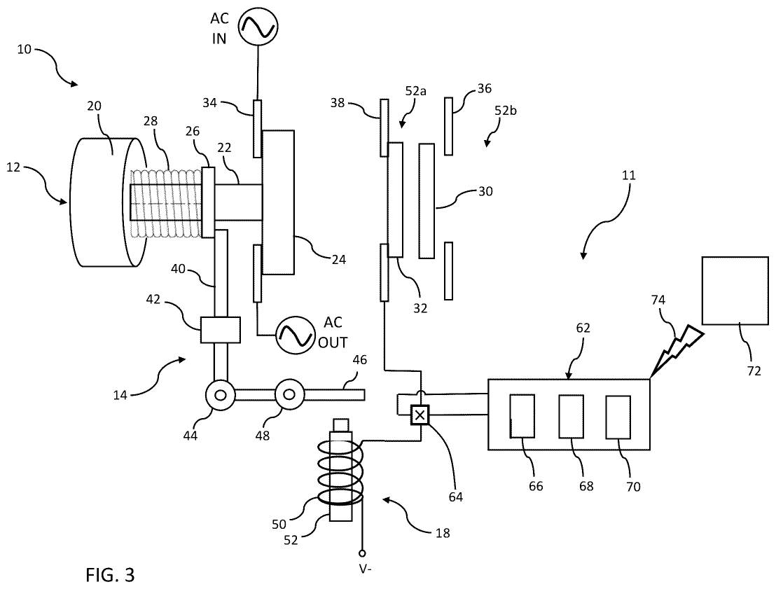

The current flow through the coil 50 of the trip coil assembly 18 changes with the various changes in configuration of the circuit breaker 10 described above as it completes the tripping sequence. As is further described below, the teachings of the present disclosure permit online monitoring of the changes in current to provide information about various components of the circuit breaker 10. In one embodiment of the present disclosure depicted in FIG. 3, an online monitoring system 11 includes an online monitor 62 coupled to a current sensor 64 to sample the current flowing through the coil 50 of the trip coil assembly 18 during tripping sequences. The online monitor 62 is also coupled to a remote device 72 to provide alarm signals and data corresponding to the tripping sequence. In one embodiment, the current sensor 64 is a Hall effect sensor configured to sense current flowing through the coil 50 of the trip current assembly 18. In other embodiments, other types of sensors may be used. The output signals of the current sensor 64 are provided to the online monitor 62, which includes a processor 66, a memory 68 and a transmitter 70. The online monitor 62 includes a plurality of other components that are not shown to simplify the description.

The memory 68 of the online monitor 62 may be any computer readable storage media. Computer storage media may include volatile and non-volatile, removable and non-removable media implemented in any method or technology for storage of information, such as computer readable instructions, data structures, or program modules. Computer storage media may include RAM, ROM, electrically erasable read-only memory (EEPROM), flash memory or other memory technology, CD-ROM, digital versatile disks (DVD) or other optical storage, magnetic cassettes, magnetic tape, magnetic disk storage or other magnetic storage devices, or any other article of manufacture which can be used to store information and which can be accessed by the processor 66. Any such computer storage media may be part of the online monitor 62. Computer storage media does not include a carrier wave or other propagated or modulated data signal.

The processor 66 of the online monitor 62 can be implemented as and/or in conjunction with a special purpose computer, a programmed microprocessor or microcontroller and peripheral integrated circuit element(s), an ASIC or other integrated circuit, a digital signal processor, a hard-wired electronic or logic circuit such as discrete element circuit, a programmable logic device or gate array such as PLD, PLA, FPGA, PAL, a special purpose computer, any comparable means, or the like. In general, any device(s) or means capable of implementing the methodology illustrated herein can be used as the processor 66 to implement the various aspects of this disclosure.

In general, the processor 66 of the online monitor 62 samples the current signals from the current sensor 64 periodically beginning at the time that the trip contact 16 closes (i.e., at the beginning of the tripping sequence shown in FIG. 2B). In one embodiment of the present disclosure, the sampling frequency is approximately 100,000 Hertz or more, which provides sufficient detail of the complex shape of the sensed current. Other higher or lower sampling frequencies may be used in other applications. In certain embodiments, a value for each sample collected during each tripping sequence is stored in the memory 68 for analysis and future access as is further described below. The processor 66 also analyzes information obtained from the samples to identify faulty or potentially faulty operation of the circuit breaker 10. The processor 66 may generate alarm signals based on this analysis, and transmit the alarm signals via the transmitter 70 to the remote device 72 as indicated at 74. The remote device 72 may be a computing device at a utility company or another device configured to receive data and alarm signals from the online monitor 62. The transmission of the alarm signals may be over a wired or wireless connection between the online monitor 62 and the remote device 72 as indicated by item 74 in FIG. 3.

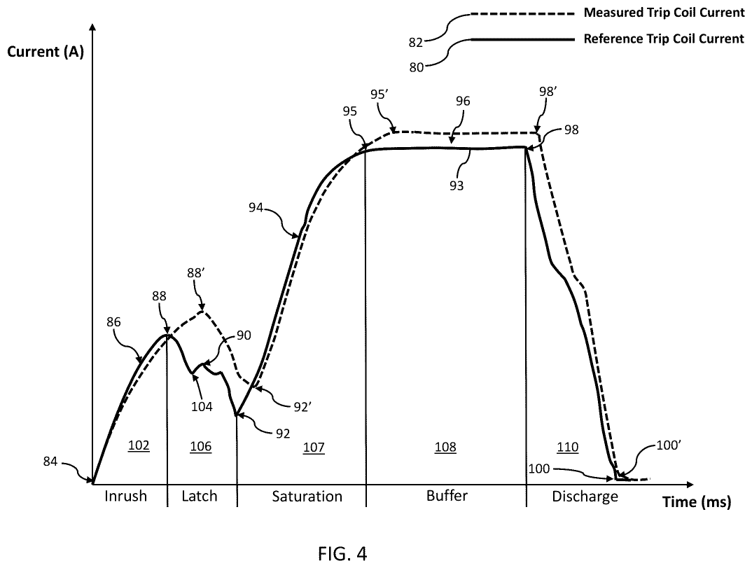

Referring now to FIG. 4, an example of a reference trip coil current signature waveform 80 (hereinafter “reference TCCSW 80”) and a measured trip coil current signature waveform 82 (hereinafter, “measured TCCSM 82”) is shown. In FIG. 4, the y-axis is current (in amperes) flowing through the coil 50 of the trip coil assembly 18 as sensed by the current sensor 64 and sampled by the processor 66 of the online monitor 62. The x-axis is time (in milliseconds). The shape of the trip coil current signature waveforms provides a window into the operation of the operating mechanisms (e.g., the trip coil assembly 18 and the latch assembly 14) of the circuit breaker 10. As described below, each peak, valley, and plateau are the result of specific activities, occurring in milliseconds during the tripping sequence of the circuit breaker 10. A rising curve is the result of increasing current through the coil 50 and occurs when the plunger 52 is working against resistance or accelerating. A falling curve is the result of decreasing current through the coil 50 and occurs when the plunger 52 is traveling with less resistance.

The reference TCCSW 80 is obtained when the circuit breaker 10 is new or fully refurbished. In other words, the reference TCCSW 80 represents the current flow through the coil 50 during a tripping sequence when the circuit breaker 10 is fully functional and operating correctly. The example measured TCCSW 82 is obtained each time the circuit breaker 10 trips as is further explained below, and a comparison of the two signature waveforms provides information about the operational status of the circuit breaker 10 at the time of the tripping sequence.

Referring to the reference TCCSW 80 of FIG. 4, the point 84 is the beginning of the trip sequence when the trip contact 16 is first closed and current through the coil 50 of the trip coil assembly 18 begins to increase from zero amperes. This corresponds to the circuit breaker 10 configuration depicted in FIG. 2B. The portion 86 of the reference TCCSW 80 shows the inrush current through the coil 50 of the trip coil assembly 18. The point 88 shows the change in current through the coil 50 as the plunger 52 begins to travel upwardly. The point 104 shows the change in current through the coil 50 when the plunger 52 strikes the actuator arm 46 of the latch assembly 14, momentarily stopping, as depicted in FIG. 2C. Between points 90 and 92, the change in current is shown as the plunger 52 of the trip coil circuit 18 moves the actuator arm 46 and the retaining arm 40 of the trip latch assembly 14 as depicted in FIG. 2D. At the point 92, the plunger 52 reaches the end of its travel and is stopped. The portion 94 of the reference TCCSW 80 shows the increase in current as the coil 50 of the trip coil assembly 18 is saturated. The current levels out at a plateau 96 when maximum current is passing through the coil 50. During this plateau 96, the main contact conductor 24 separates from the main contacts 34 as depicted in FIG. 2E (point 93). Finally, at point 98, the contact 32 of the first auxiliary switch 56a separates from auxiliary contacts 38 as depicted in FIGS. 2F and 2G, and the coil 50 is deenergized to essentially zero amperes at point 100.

The reference TCCSW 80 may be viewed as having a plurality of areas representing different stages in the tripping sequence described above. An initial inrush area 102 may be defined as the area under the reference TCCSW 80 between the point 84 (start of the current flow in the tripping sequence) and the first peak at point 88. A subsequent latch area 106 may be defined as the area under the reference TCCSW 80 between the point 88 and the point 92, which represents the deepest valley of the reference TCCSW 80 and the point at which the plunger 52 reaches the end of its travel. A subsequent saturation area 107 may be defined as the area under the reference TCCSW 80 between the deepest valley at point 92 and the point 95, where the coil 50 is saturated with maximum current and the amplitude values stop increasing. A subsequent buffer area 108 may be defined as the area under the reference TCCSW 80 between the point 95 and the point 98, where the trip contact 16 is opened and current is no longer supplied to the coil 50. Finally, a discharge area 110 may be defined as the area under the reference TCCSW 80 between the point 98 and the point 100 where the coil 50 is fully deenergized.

The online monitor 62 is configured to analyze the health of operation of the circuit breaker 10 by measuring the measured TCCSW 82 each time the circuit breaker 10 is tripped and comparing aspects of the measured signature to the reference signature as is further described below. The online monitor 62 can also determine an overall opening time associated with each tripping sequence of the circuit breaker 10. The opening time generally represents the speed and effectiveness of the trip coil assembly 18 as an electro-mechanical device (or solenoid) in initiating the opening of the circuit breaker 10. Generally speaking, longer opening times are undesirable and may indicate a defective trip coil assembly 18, a sticking latch assembly 14, slow breaker opening travel, a lack of lubrication (e.g., solidified grease), a weakly tensioned spring 28, or a variety of other undesirable conditions. The opening time of the reference TCCSW 80 is shown in FIG. 4 as the time between point 84 and point 98.

The processor 66 of the online monitor 62 analyzes the measured opening time and compares it to a predetermined acceptable limit. When the measured opening time exceeds the predetermined acceptable limit, the processor 66 causes the transmitter 70 to transmit an alarm signal to the remote device 72, which should prompt utility maintenance people to investigate and diagnose the problem.

As indicated herein, however, the online monitor 62 is capable of providing much more information to the utility maintenance people with specific data that indicates the health and performance of the trip coil assembly 18 and the latch assembly 14 of the circuit breaker 10. This data informs the utility of developing problems so preventive measures can be proactively taken, increasing the reliability and performance of the circuit breaker 10.

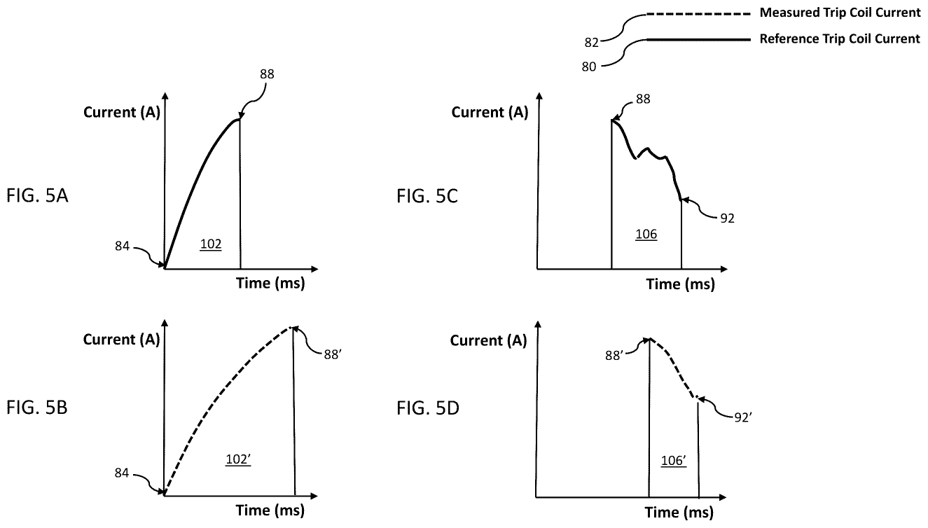

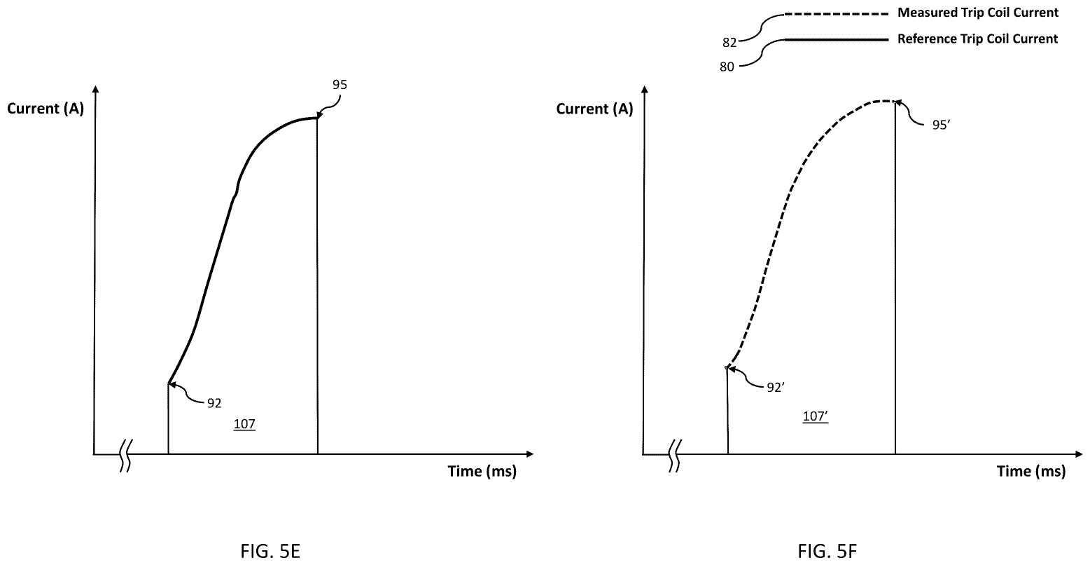

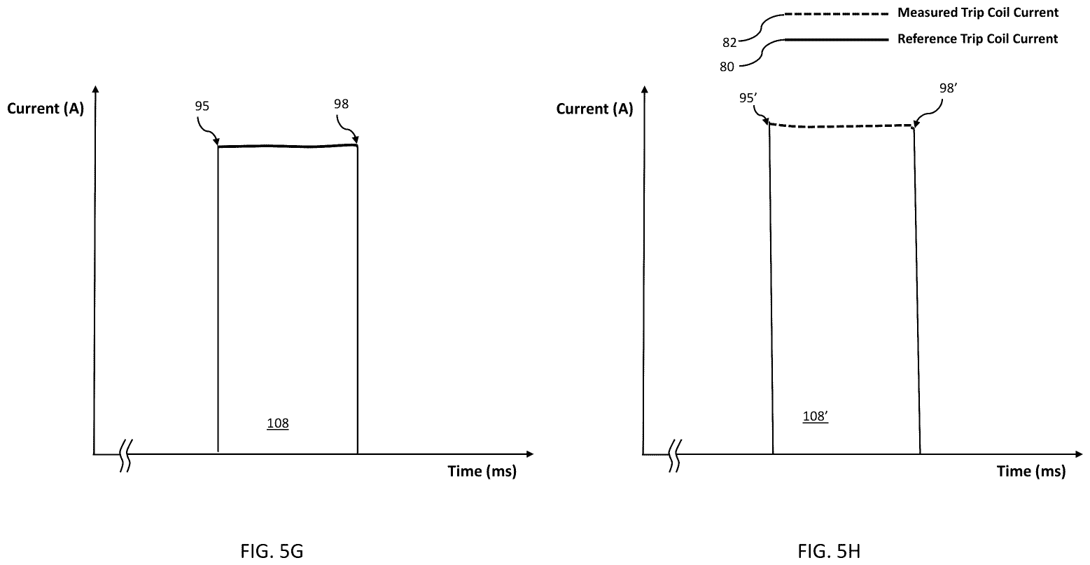

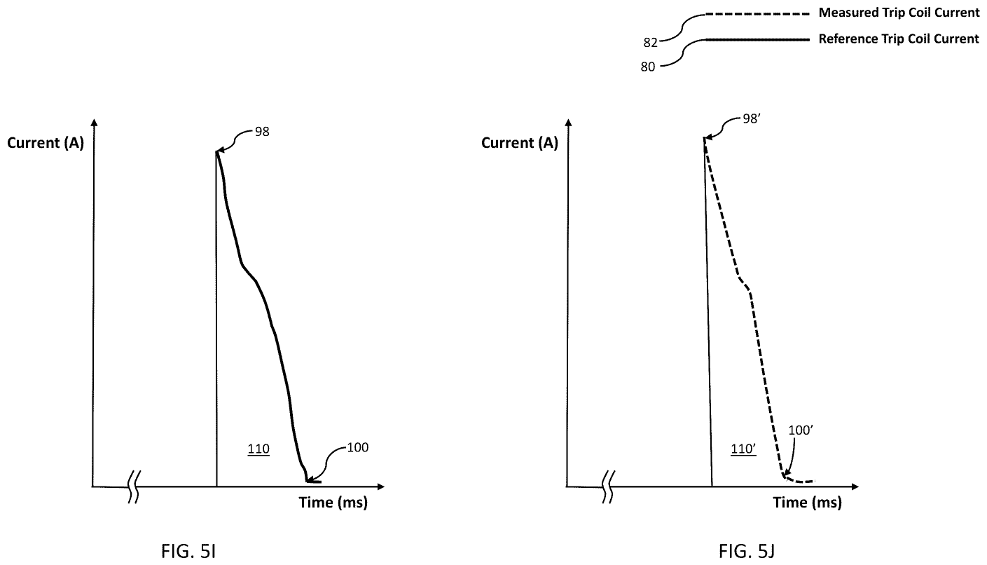

Referring now to FIGS. 5A through 5J, the relative sizes of each area under the reference TCCSW 80 and the example measured TCCSW 82 are shown. Depending upon the amplitude and time duration between the various points in the signatures 80, 82, the areas will likely be different. In FIGS. 5A and 5B, the inrush area 102 of the reference TCCSW 80 is the area under the current curve between the time corresponding to point 84 (i.e., time zero) to the time corresponding to point 88. Similarly, the inrush area 102′ of the measured TCCSW 82 is the area under the current curve between the time corresponding to point 84 and to the time corresponding to point 88′, which in this example is later than the time corresponding to point 88 on the reference TCCSW 80. A similar description applies to the latch areas 106, 106′ depicted in FIGS. 5C and 5D, respectively, the saturation areas 107, 107′ depicted in FIGS. 5E and 5F, the buffer areas 108, 108′ depicted in FIGS. 5G and 5H, respectively, and the discharge areas 110, 110′ depicted in FIGS. 51 and 5J, respectively.

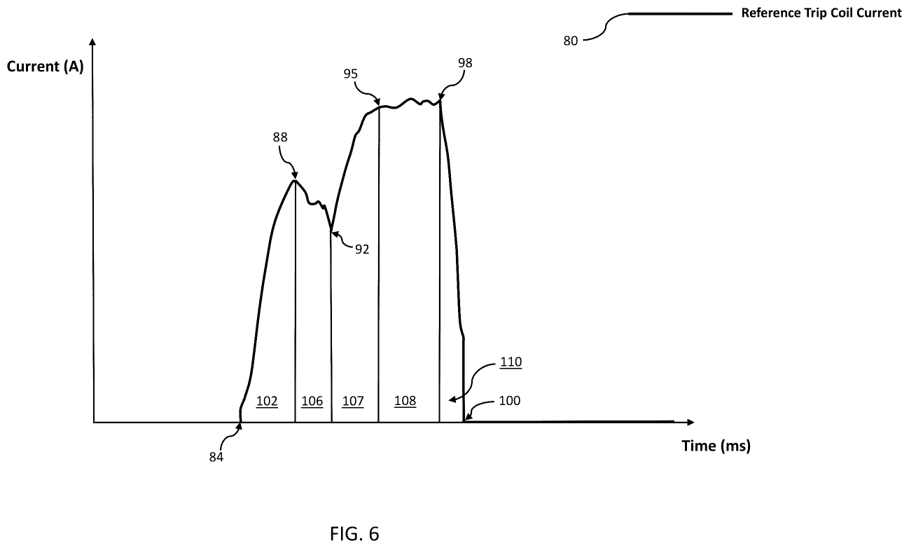

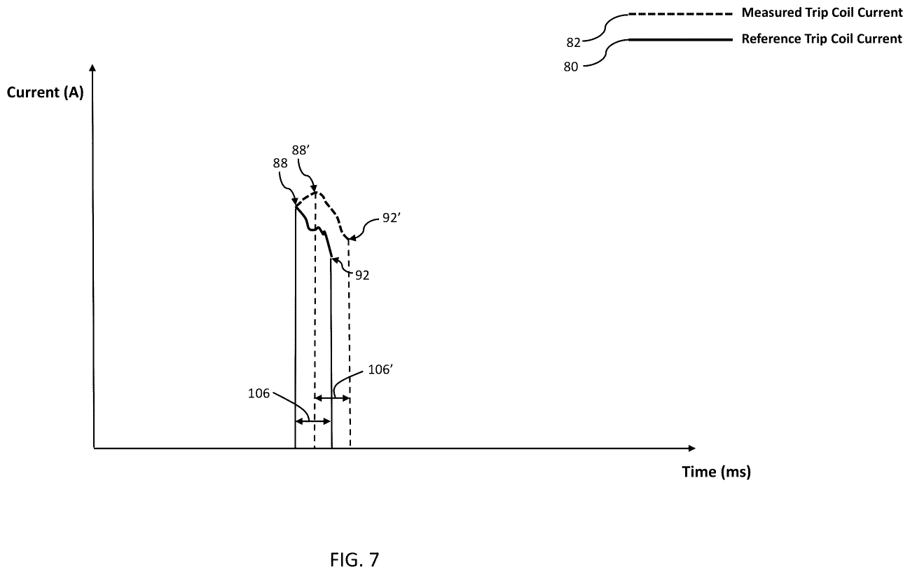

FIG. 6 provides another example of a reference TCCSW 80 showing each of the inrush area 102, the latch area 104, the saturation area 107, the buffer area 108 and the discharge area 110. FIG. 7 shows a comparison of the reference TCCSW 80 throughout the latch area 104 with a measured TCCSW 82 during the same period. As shown, the amplitude of the measured TCCSW 82 at the point 88′ (the first peak) is substantially higher than the amplitude of the reference TCCSW 80 at the point 88. This references a high latch current in the measured TCCSW 82 which may indicate a problem with the latch assembly 14 of the circuit breaker 10.

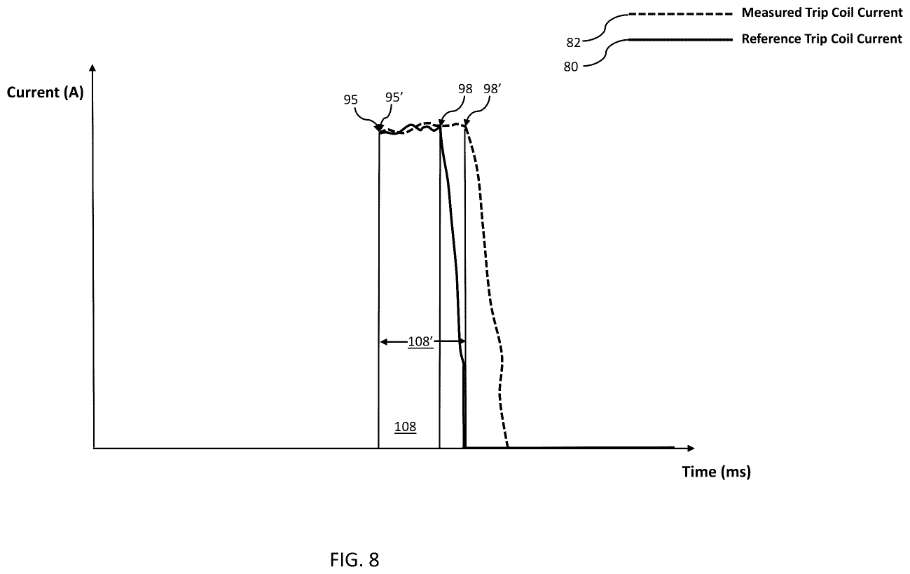

FIG. 8 shows a comparison of the reference TCCSW 80 throughout the buffer area 108 with a measured TCCSW 82 throughout the buffer area 108′. As shown, the time duration of the measured buffer area 108′ is substantially longer than the time duration of the reference buffer area 108. This long measured buffer area 108′ may indicate a problem with slow breaker travel (e.g., weak spring 28, poor lubrication, etc.).

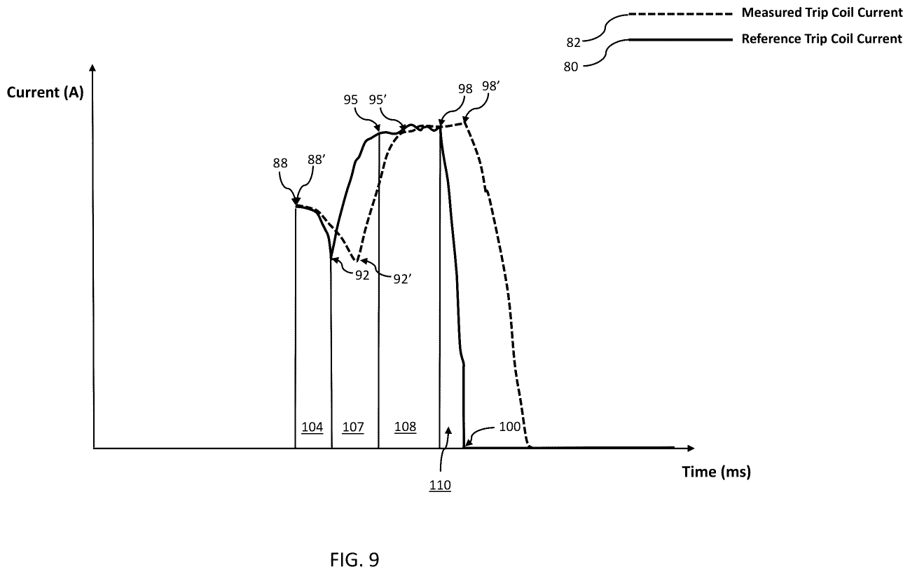

FIG. 9 illustrates an example of a slow latch assembly 14. As shown, the time for the measured TCCSW 82 to reach the point 92′ where the plunger 52 has reached its end of travel is substantially longer than the time required for the reference TCCSW 80. Similarly, the TCCSW 82 takes substantially longer to reach the point 95′ representing maximum current on the coil 50 and the point 98′ representing the opening of the first auxiliary switch 52a. These delays may indicate problems with the trip coil assembly 18 and/or the latch mechanism lubrication.

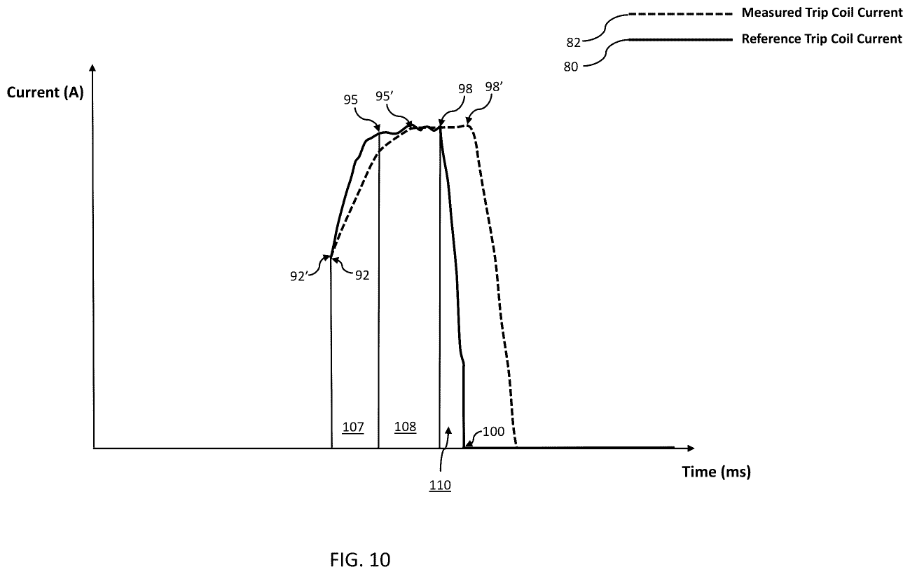

FIG. 10 depicts an example measured TCCSW 82 reflecting slow saturation of the coil 50. As shown, while the measured TCCSW 82 reaches the deepest valley point 92′ at the same time as the reference TCCSW 80, it takes the measured TCCSW 82 substantially longer to reach the point of maximum current in the coil 50 (i.e., point 95′) that it took the reference TCCSW 82 of the circuit breaker 10 to reach the end of the saturation area 107. This slow saturation may indicate a problem with the coil 50.

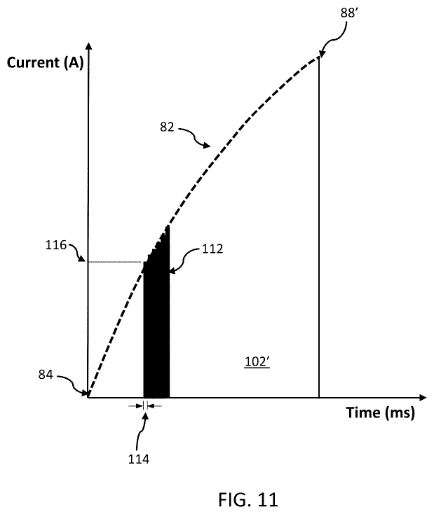

Referring now to FIG. 11, by using a sum of current-times-time (Sum I*T) method to mathematically quantify the areas under the signature waveforms 80, 82, the mathematical value of each area of the measured TCCSW 82 (i.e., inrush area 102′, latch area 106′, saturation area 107′, buffer area 108′ and discharge area 110′) can be easily compared to the values of the corresponding areas of the reference TCCSW 80 (i.e., inrush area 102, latch area 106, saturation area 107, buffer area 108 and discharge area 110). For example, referring to FIG. 11, for each sample 112 (only six shown) of the measured TCCSW 82, the duration of the sample time 114 (on the order of microseconds) is multiplied by the amplitude 116 of the measured current to obtain one sample value for the inrush area 102′. The individual sample values are added together between the time corresponding to point 84 and the time corresponding to the point 88′ to yield the total value of the measured inrush area 102′. This total value is compared to the total value of the corresponding inrush area 102 of the reference TCCSW 80 which was previously measured, calculated and stored in the memory 68. The processor 66 may determine a percentage difference between the two values and compare the percentage difference to programmable alarm limits. The percentage difference may also be transmitted to the remote device 72, further analyzed by the remote device 72, or displayed on a display (not shown) of the online monitor 62 and/or the remote device 72. If the percentage difference exceeds one of the programmable alarm limits, then the processor 66 may cause the transmitter 70 to send an alarm signal to the remote device 72.

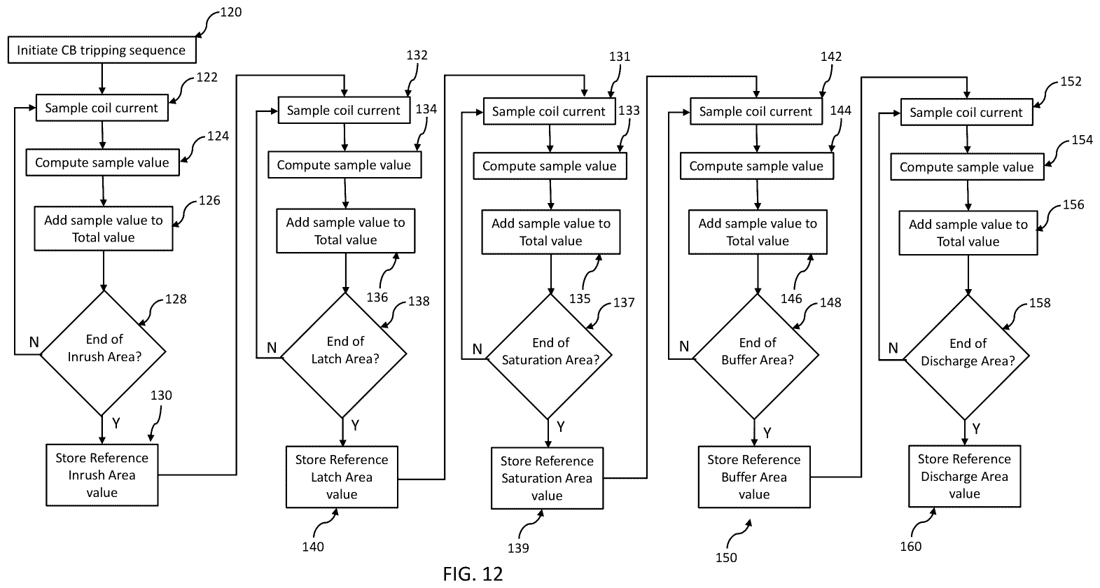

A method for trip coil current monitoring is depicted in FIGS. 12 through 14. FIG. 12 depicts the process for establishing reference values for the inrush area 102, the latch area 106, the saturation area 107, the buffer area 108 and the discharge area 110 from the reference TCCSW 80. The process begins at step 120 when a new or refurbished circuit breaker 10 is installed. At step 120, a tripping sequence is initiated by causing the trip contact 16 to close. At step 122, the processor 66 of the online monitor 62 receives a first sample of the current passing through the coil 50 as measured by the current sensor 64. At step 124, the processor 66 then computes a sample value of the first sample by multiplying the sample time 114 by the amplitude 116 of the sample as described above. At step 126, the processor 66 stores the sample value in the memory 68. At step 128, the processor 66 determines whether the end of the inrush area 102 has been reached. The processor 66 makes this determination by comparing previously stored sample values to identify a first peak (corresponding to point 88, see FIG. 4) in the sampled current. In this case, there are no previously stored sample values and the processor 66 therefore determines that the end of the inrush area 102 has not been reached. Accordingly, the method returns to step 122 and the processor 66 receives another sample of the current as measured by the current sensor 64. The processor 66 continues to receive current samples, compute sample values, store the sample values in the memory 68, adding new sample values to previously computed and stored sample values, and determine whether the end of the inrush area 102 has been reached. In other words, steps 122, 124, 126 and 128 are repeated until the processor 66 determines that the end of the inrush area 102 has been reached. When the processor 66 determines that the previously stored sample values represent consistently increasing current through the coil 50, followed by a peak, followed by consistently decreasing current through the coil 50, the processor 66 stores the sum of all the sample values up until the point 88 as the final reference inrush area value at step 130, and the method proceeds to step 132.

At step 132, the processor 66 of the online monitor 62 receives a first sample of the current passing through the coil 50 as measured by the current sensor 64 representing the first sample of the latch area 106 of the reference TCCSW 80. At step 134, the processor 66 then computes a sample value of the first sample by multiplying the sample time 114 by the amplitude 116 of the sample as described above. At step 136, the processor 66 stores the sample value in the memory 68. At step 138, the processor 66 determines whether the end of the latch area 106 has been reached. The processor 66 makes this determination by comparing previously stored sample values to identify the deep valley at the point 92 (FIG. 4) where the plunger 52 is stopped. The deep valley of point 92 is identified by identifying an end of decreasing amplitudes and the start of increasing amplitudes in the TCCSW 80. In this case, there are no previously stored sample values for the latch area 106 and the processor 66 therefore determines that the end of the latch area 106 has not been reached. Accordingly, the method returns to step 132 and the processor 66 receives another sample of the current as measured by the current sensor 64. The processor 66 continues to receive current samples, compute sample values, store the sample values in the memory 68, adding new sample values to previously computed and stored sample values, and determine whether the end of the latch area 106 has been reached. In other words, steps 132, 134, 136 and 138 are repeated until the processor 66 determines that the end of the latch area 106 has been reached. When the processor 66 determines that the previously stored sample values represent the end of the latch area 106 (i.e., the point 92 is identified), the processor 66 stores the sum of all the sample values up until the point 92 as the final reference latch area value at step 140, and the method proceeds to step 131.

At step 131, the processor 66 of the online monitor 62 receives a first sample of the current passing through the coil 50 as measured by the current sensor 64 representing the first sample of the saturation area 107 of the reference TCCSW 80. At step 133, the processor 66 then computes a sample value of the first sample by multiplying the sample time 114 by the amplitude 116 of the sample as described above. At step 135, the processor 66 stores the sample value in the memory 68. At step 137, the processor 66 determines whether the end of the saturation area 107 has been reached. The processor 66 makes this determination by comparing previously stored sample values to identify the point 95 (FIG. 4), where the coil 50 is saturated with maximum current. The point 95 is identified by identifying an end of increasing amplitudes and the beginning of the plateau 96 (FIG. 4). In this case, there are no previously stored sample values for the saturation area 107 and the processor 66 therefore determines that the end of the saturation area 107 has not been reached. Accordingly, the method returns to step 131 and the processor 66 receives another sample of the current as measured by the current sensor 64. The processor 66 continues to receive current samples, compute sample values, store the sample values in the memory 68, adding new sample values to previously computed and stored sample values, and determine whether the end of the saturation area 107 has been reached. In other words, steps 131, 133, 135 and 137 are repeated until the processor 66 determines that the end of the saturation area 107 has been reached. When the processor 66 determines that the previously stored sample values represent the end of the saturation area 106 (i.e., the point 95 is identified), the processor 66 stores the sum of all the sample values up until the point 95 as the final reference saturation area value at step 139, and the method proceeds to step 142.

At step 142, the processor 66 of the online monitor 62 receives a first sample of the current passing through the coil 50 as measured by the current sensor 64 representing the first sample of the buffer area 108 of the reference TCCSW 80. At step 144, the processor 66 then computes a sample value of the first sample by multiplying the sample time 114 by the amplitude 116 of the sample as described above. At step 146, the processor 66 stores the sample value in the memory 68. At step 148, the processor 66 determines whether the end of the buffer area 108 has been reached. The processor 66 makes this determination by comparing previously stored sample values to identify point 98 (FIG. 4) where the first auxiliary switch 52a is opened. At point 98, the amplitudes are no longer equal, but begin to decrease. In this case, there are no previously stored sample values for the buffer area 108 and the processor 66 therefore determines that the end of the buffer area 108 has not been reached. Accordingly, the method returns to step 142 and the processor 66 receives another sample of the current as measured by the current sensor 64. The processor 66 continues to receive current samples, compute sample values, store the sample values in the memory 68, adding new sample values to previously computed and stored sample values, and determine whether the end of the buffer area 108 has been reached. In other words, steps 142, 144, 146 and 148 are repeated until the processor 66 determines that the end of the buffer area 108 has been reached. When the processor 66 determines that the previously stored sample values represent the beginning of decreasing amplitudes in the TCCSW 80 (i.e., the point 98 has been reached), the processor 66 stores the sum of all of the sample values up until the point 98 as the final reference buffer area value at step 150, and the method proceeds to step 152.

At step 152, the processor 66 of the online monitor 62 receives a first sample of the current passing through the coil 50 as measured by the current sensor 64 representing the first sample of the discharge area 110 of the reference TCCSW 80. At step 154, the processor 66 then computes a sample value of the first sample by multiplying the sample time 114 by the amplitude 116 of the sample as described above. At step 156, the processor 66 stores the sample value in the memory 68. At step 158, the processor 66 determines whether the end of the discharge area 110 has been reached. The processor 66 makes this determination by identifying point 100 (FIG. 4) where the coil 50 is completely discharged and the measured current is essentially zero. In this case, the first sample is not zero and the processor 66 therefore determines that the end of the discharge area 110 has not been reached. Accordingly, the method returns to step 152 and the processor 66 receives another sample of the current as measured by the current sensor 64. The processor 66 continues to receive current samples, compute sample values, store the sample values in the memory 68, adding new sample values to previously computed and stored sample values, and determine whether the end of the discharge area 110 has been reached. In other words, steps 152, 154, 156 and 158 are repeated until the processor 66 determines that the end of the discharge area 110 has been reached. When the processor 66 determines that the measured current through the coil 50 is zero (i.e., point 100), the processor 66 stores the sum of all the sample values as the final reference discharge area value at step 160.

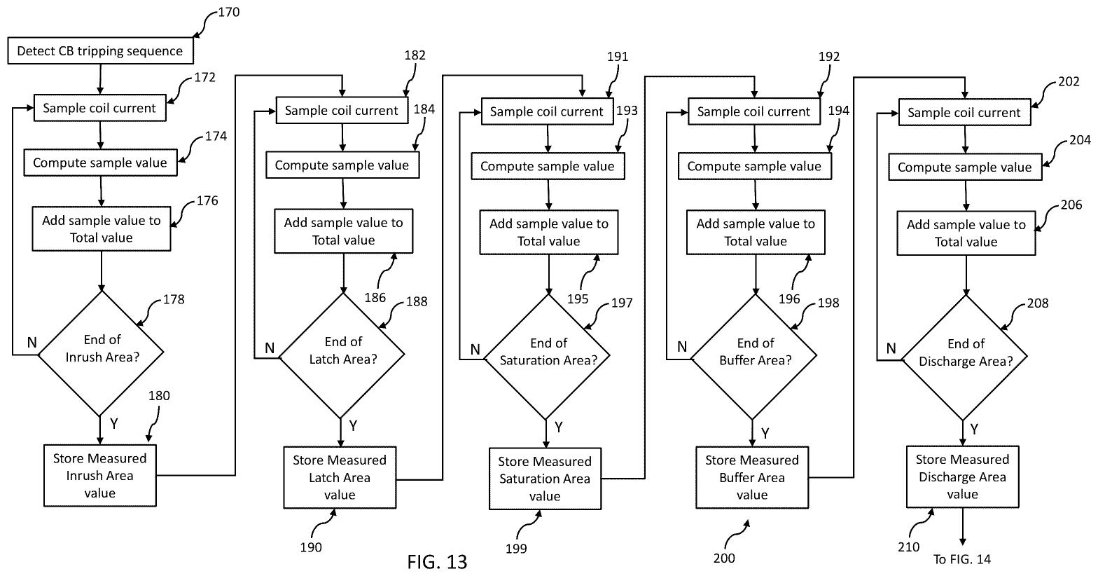

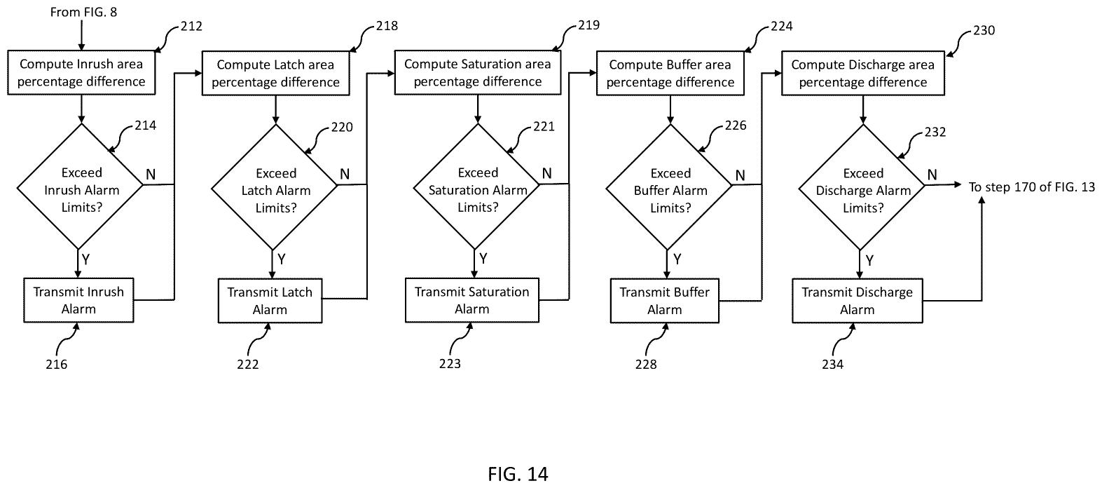

After the final reference values for the inrush area 102, the latch area 106, the saturation area 107, the buffer area 108 and the discharge area 110 of the reference TCCSW 80 have been computed and stored in the memory 70 of the online monitor 62 as described above, the processor 66 of the online monitor 62 continuously monitors the state of the trip contact 16 to determine when a tripping sequence has begun (i.e., the trip contact 16 has closed) and a measured TCCSW 82 should be collected. FIG. 13 depicts the process for establishing measured values for the inrush area 102′, the latch area 106′, the saturation area 107′, the buffer area 108′ and the discharge area 110′ from the measured TCCSW 82. The process begins at step 170 when a tripping sequence is detected (i.e., the trip contact 16 has closed). At step 172, the processor 66 of the online monitor 62 receives a first sample of the current passing through the coil 50 as measured by the current sensor 64. At step 174, the processor 66 then computes a sample value of the first sample by multiplying the sample time 114 by the amplitude 116 of the sample as described above. At step 176, the processor 66 stores the sample value in the memory 68. At step 178, the processor 66 determines whether the end of the inrush area 102′ has been reached as described above. In this case, there are no previously stored sample values and the processor 66 therefore determines that the end of the inrush area 102′ has not been reached. Accordingly, the method returns to step 172 and the processor 66 receives another sample of the current as measured by the current sensor 64. The processor 66 continues to receive current samples, compute sample values, store the sample values in the memory 68, adding new sample values to previously computed and stored sample values, and determine whether the end of the inrush area 102′ has been reached. In other words, steps 172, 174, 176 and 178 are repeated until the processor 66 determines that the end of the inrush area 102′ has been reached. When the end of the inrush area 102′ has been reached, the processor 66 stores the sum of all the sample values as the final measured inrush area value at step 180, and the method proceeds to step 182.

At step 182, the processor 66 of the online monitor 62 receives a first sample of the current passing through the coil 50 as measured by the current sensor 64 representing the first sample of the latch area 106′ of the measured TCCSW 82. At step 184, the processor 66 then computes a sample value of the first sample by multiplying the sample time 114 by the amplitude 116 of the sample as described above. At step 186, the processor 66 stores the sample value in the memory 68. At step 188, the processor 66 determines whether the end of the latch area 106′ has been reached as described above. In this case, there are no previously stored sample values for the latch area 106′ and the processor 66 therefore determines that the end of the latch area 106′ has not been reached. Accordingly, the method returns to step 182 and the processor 66 receives another sample of the current as measured by the current sensor 64. The processor 66 continues to receive current samples, compute sample values, store the sample values in the memory 68, adding new sample values to previously computed and stored sample values, and determine whether the end of the latch area 106′ has been reached. In other words, steps 182, 184, 186 and 188 are repeated until the processor 66 determines that the end of the latch area 106′ has been reached. When the processor 66 determines that the end of the latch area 106′ has been reached, the processor 66 stores the sum of all of the sample values as the final measured latch area value at step 190, and the method proceeds to step 191.

At step 191, the processor 66 of the online monitor 62 receives a first sample of the current passing through the coil 50 as measured by the current sensor 64 representing the first sample of the saturation area 107′ of the measured TCCSW 82. At step 193, the processor 66 then computes a sample value of the first sample by multiplying the sample time 114 by the amplitude 116 of the sample as described above. At step 195, the processor 66 stores the sample value in the memory 68. At step 197, the processor 66 determines whether the end of the saturation area 107′ has been reached as described above. In this case, there are no previously stored sample values for the saturation area 107′ and the processor 66 therefore determines that the end of the saturation area 107′ has not been reached. Accordingly, the method returns to step 191 and the processor 66 receives another sample of the current as measured by the current sensor 64. The processor 66 continues to receive current samples, compute sample values, store the sample values in the memory 68, adding new sample values to previously computed and stored sample values, and determine whether the end of the saturation area 107′ has been reached. In other words, steps 191, 193, 195 and 197 are repeated until the processor 66 determines that the end of the saturation area 107′ has been reached. When the processor 66 determines that the end of the saturation area 107′ has been reached, the processor 66 stores the sum of all the sample values as the final measured saturation area value at step 199, and the method proceeds to step 192.

At step 192, the processor 66 of the online monitor 62 receives a first sample of the current passing through the coil 50 as measured by the current sensor 64 representing the first sample of the buffer area 108′ of the measured TCCSW 82. At step 194, the processor 66 then computes a sample value of the first sample by multiplying the sample time 114 by the amplitude 116 of the sample as described above. At step 196, the processor 66 stores the sample value in the memory 68. At step 198, the processor 66 determines whether the end of the buffer area 108′ has been reached. The processor 66 makes this determination by comparing previously stored sample values to identify point 98′ (FIG. 4) where the first auxiliary switch 52a is opened. In this case, there are no previously stored sample values for the buffer area 108′ and the processor 66 therefore determines that the end of the buffer area 108′ has not been reached. Accordingly, the method returns to step 192 and the processor 66 receives another sample of the current as measured by the current sensor 64. The processor 66 continues to receive current samples, compute sample values, store the sample values in the memory 68, adding new sample values to previously computed and stored sample values, and determine whether the end of the buffer area 108′ has been reached. In other words, steps 192, 194, 196 and 198 are repeated until the processor 66 determines that the end of the buffer area 108′ has been reached. When the processor 66 determines that the previously stored sample values represent include a decrease in the amplitude of the measured TCCSW 82, the processor 66 stores the sum of all the sample values up until that decrease as the final measured buffer area value at step 200, and the method proceeds to step 202.

At step 202, the processor 66 of the online monitor 62 receives a first sample of the current passing through the coil 50 as measured by the current sensor 64 representing the first sample of the discharge area 110′ of the measured TCCSW 82. At step 204, the processor 66 then computes a sample value of the first sample by multiplying the sample time 114 by the amplitude 116 of the sample as described above. At step 206, the processor 66 stores the sample value in the memory 68. At step 208, the processor 66 determines whether the end of the discharge area 110′ has been reached. The processor 66 makes this determination by identifying point 100′ (FIG. 4) where the coil 50 is completely discharged and the measured current is essentially zero. In this case, the first sample is not zero and the processor 66 therefore determines that the end of the discharge area 110′ has not been reached. Accordingly, the method returns to step 202 and the processor 66 receives another sample of the current as measured by the current sensor 64. The processor 66 continues to receive current samples, compute sample values, store the sample values in the memory 68, adding new sample values to previously computed and stored sample values, and determine whether the end of the discharge area 110′ has been reached. In other words, steps 202, 204, 206 and 208 are repeated until the processor 66 determines that the end of the discharge area 110′ has been reached. When the processor 66 determines that the measured current through the coil 50 is zero (i.e., point 100′), the processor 66 stores the sum of all of the sample values as the final measured discharge area value at step 210 and the method proceeds to step 212 of FIG. 14.

At step 212, the processor 66 computes a percentage difference between the final reference inrush area value (stored in the memory 68 at step 130 of FIG. 12) and the final measured inrush area value (stored in the memory 68 at step 180 of FIG. 13). In one embodiment, the processor 66 subtracts the final reference inrush area value from the final measured inrush area value and divides the difference (positive or negative) by the final reference inrush area value. For example, if the final reference inrush area value is 1.2 and the final measured inrush area value is 1.4, the percentage difference for the inrush area is 16.67% (i.e., (1.4−1.2)/1.2=0.1667). Next, at step 214 the processor 66 determines whether the computed percentage difference for the inrush area values exceeds at least one inrush alarm limit. In certain embodiments, the processor 66 compares the computed percentage difference for the inrush area values to a high inrush alarm limit and a low inrush alarm limit. In such embodiments, if the computed percentage difference for the inrush area values is greater than the high inrush alarm limit or less than the low inrush alarm limit, the processor 66 causes the transmitter 70 of the online monitor 62 to transmit an inrush alarm signal to the remote device 72 as indicated by step 216 and the method advances to step 218. If, on the other hand, the computed percentage difference for the inrush area values falls between the high and low inrush alarm limits, then the method simply advances to step 218.

At step 218, the processor 66 computes a percentage difference between the final reference latch area value (stored in the memory 68 at step 140 of FIG. 12) and the final measured inrush area value (stored in the memory 68 at step 190 of FIG. 13). In one embodiment, the processor 66 subtracts the final reference latch area value from the final measured latch area value and divides the difference (positive or negative) by the final reference latch area value. For example, if the final reference latch area value is 1.2 and the final measured latch area value is 1.4, the percentage difference for the latch area is 16.67% (i.e., (1.4−1.2)/1.2=0.1667). Next, at step 220 the processor 66 determines whether the computed percentage difference for the latch area values exceeds at least one latch alarm limit. In certain embodiments, the processor 66 compares the computed percentage difference for the latch area values to a high latch alarm limit and a low latch alarm limit. In such embodiments, if the computed percentage difference for the latch area values is greater than the high latch alarm limit or less than the low latch alarm limit, the processor 66 causes the transmitter 70 of the online monitor 62 to transmit a latch alarm signal to the remote device 72 as indicated by step 222 and the method advances to step 219. If, on the other hand, the computed percentage difference for the latch area values falls between the high and low latch alarm limits, then the method simply advances to step 219.

At step 219, the processor 66 computes a percentage difference between the final reference saturation area value (stored in the memory 68 at step 139 of FIG. 12) and the final measured saturation area value (stored in the memory 68 at step 199 of FIG. 13). In one embodiment, the processor 66 subtracts the final reference saturation area value from the final measured saturation area value and divides the difference (positive or negative) by the final reference saturation area value. For example, if the final reference saturation area value is 1.2 and the final measured saturation area value is 1.4, the percentage difference for the saturation area is 16.67% (i.e., (1.4−1.2)/1.2=0.1667). Next, at step 221 the processor 66 determines whether the computed percentage difference for the saturation area values exceeds at least one saturation alarm limit. In certain embodiments, the processor 66 compares the computed percentage difference for the saturation area values to a high saturation alarm limit and a low saturation alarm limit. In such embodiments, if the computed percentage difference for the saturation area values is greater than the high saturation alarm limit or less than the low saturation alarm limit, the processor 66 causes the transmitter 70 of the online monitor 62 to transmit a saturation alarm signal to the remote device 72 as indicated by step 223 and the method advances to step 224. If, on the other hand, the computed percentage difference for the saturation area values falls between the high and low saturation alarm limits, then the method simply advances to step 224.

At step 224, the processor 66 computes a percentage difference between the final reference buffer area value (stored in the memory 68 at step 150 of FIG. 12) and the final measured buffer area value (stored in the memory 68 at step 200 of FIG. 13). In one embodiment, the processor 66 subtracts the final reference buffer area value from the final measured buffer area value and divides the difference (positive or negative) by the final reference buffer area value. For example, if the final reference buffer area value is 1.2 and the final measured buffer area value is 1.4, the percentage difference for the buffer area is 16.67% (i.e., (1.4−1.2)/1.2=0.1667). Next, at step 226 the processor 66 determines whether the computed percentage difference for the buffer area values exceeds at least one buffer alarm limit. In certain embodiments, the processor 66 compares the computed percentage difference for the buffer area values to a high buffer alarm limit and a low buffer alarm limit. In such embodiments, if the computed percentage difference for the buffer area values is greater than the high buffer alarm limit or less than the low buffer alarm limit, the processor 66 causes the transmitter 70 of the online monitor 62 to transmit a buffer alarm signal to the remote device 72 as indicated by step 228 and the method advances to step 230. If, on the other hand, the computed percentage difference for the buffer area values falls between the high and low buffer alarm limits, then the method simply advances to step 230.

At step 230, the processor 66 computes a percentage difference between the final reference discharge area value (stored in the memory 68 at step 160 of FIG. 12) and the final measured discharge area value (stored in the memory 68 at step 210 of FIG. 13). In one embodiment, the processor 66 subtracts the final reference discharge area value from the final measured discharge area value and divides the difference (positive or negative) by the final reference discharge area value. For example, if the final reference discharge area value is 1.2 and the final measured discharge area value is 1.4, the percentage difference for the discharge area is 16.67% (i.e., (1.4−1.2)/1.2=0.1667). Next, at step 232 the processor 66 determines whether the computed percentage difference for the discharge area values exceeds at least one discharge alarm limit. In certain embodiments, the processor 66 compares the computed percentage difference for the discharge area values to a high discharge alarm limit and a low discharge alarm limit. In such embodiments, if the computed percentage difference for the discharge area values is greater than the high discharge alarm limit or less than the low discharge alarm limit, the processor 66 causes the transmitter 70 of the online monitor 62 to transmit a discharge alarm signal to the remote device 72 as indicated by step 234 and the method returns to step 170 of FIG. 13 where the online monitor 62 waits to detect close sequence (and then another tripping sequence). If, on the other hand, the computed percentage difference for the discharge area values falls between the high and low discharge alarm limits, then the method simply advances to step 170 of FIG. 13.

In other embodiments of the present disclosure, the online monitoring system 11 and corresponding methods may be used to analyze the measured TCCSW 82 in various other ways and can even offer diagnostic observations and corrective action recommendations. Table 1 below describes some of the other measurements that may be taken using the online monitor 62, the manner in which the measurements may be taken, the significance of the measurements and one or more benefits knowledge of the measurements may provide to the utility companies. References below are made to the portions of the reference TCCSW 80 depicted in FIG. 4, unless otherwise specified, but are equally applicable to the measured TCCSW 82.

TABLE 1

| What can be | | | Significance to the |
|---|---|---|---|
| measured? | How is it measured? | What it represents | utility |
| Excitation | Starts when the coil 50 | The time it takes the | Basic health |
| Time | is energized (point 84) | coil 50 to generate | (conductance) of the |
| | and ends at the first | enough magnetic flux | coil 50 |
| | peak (point 88) | to move the plunger | |
| | | 52 | |
| Latch Time | Starts at the first peak | The travel time of the | A longer time means |
| | (point 88) and ends at | plunger 52 until it | the coil 50 is weak or |
| | the deepest valley | stops moving | the plunger 52 is |
| | (point 92) | | obstructed |
| Saturation | Starts at the deepest | The time it takes to | A longer time means |
| Time | valley (point 92) and | saturate the coil 50 | resistance of the coil |
| | ends at the plateau | with maximum current | 50 is high |
| | (point 95) | | |
| Buffer Time | Starts as the current | Travel speed of the | A longer time means |
| | stabilizes at its highest | breaker 10 | the interrupter |
| | and ends when the | | mechanism is slow, |
| | current begins to | | sticking or the spring |
| | decrease (first auxiliary | | 28 is weak |
| | switch 52a opens) | | |
| Interrupting | Starts at the deepest | The time it takes the | A longer time means |
| Time | valley (point 92) and | interrupter to separate | the interrupter |
| | ends when main | and extinguish all arc | mechanism is slow or |
| | contact fault current | current measured by | the dielectric is poor |
| | stops (point 93) | the online monitor 62 | |
| Aux Contact | Starts at the deepest | The acceleration time | A longer time means |
| Time | valley (point 92) and | of the interrupter | the interrupter |
| | ends at the falling edge | mechanism | mechanism is |
| | after the plateau 96 | | sticking or the spring |
| | (point 98) | | 28 is weak |
| End Time | Starts at the falling | The time it takes the | A longer time may |
| | edge after the plateau | coil 50 to discharge | indicate the first |
| | 96 (point 98) and ends | after the first auxiliary | auxiliary switch 52a |
| | when coil 50 current | switch 52a opens | is not fully opening |
| | stops (point 100) | | and arcing |
| Inrush | First current peak | The ability of the coil | Basic health |
| Current | (point 88) | 50 to generate a | (conductance) of the |
| | | magnetic field | coil 50 |
| | | sufficient to accelerate | |
| | | the plunger 52 | |
| Buffer | Deepest current valley | The speed of the latch | Higher current |
| Current | (point 92) | assembly 14 | means slower latch |
| | | | assembly 14 velocity |
| Full Current | Current Plateau 96 | The maximum current | Represents the |
| | | to the coil 50 | battery's ability to |
| | | | sustain current |
| | | | through the |
| | | | resistance of the coil |
| | | | 50 |
| Time Since | Each tripping | The time between | The longer the time |
| Last | sequence is time and | tripping sequences | the higher the |
| Operation | date coded | | likelihood of a slow |
| | | | next tripping |
| | | | sequence due to |
| | | | sticking bearings, |
| | | | etc. |

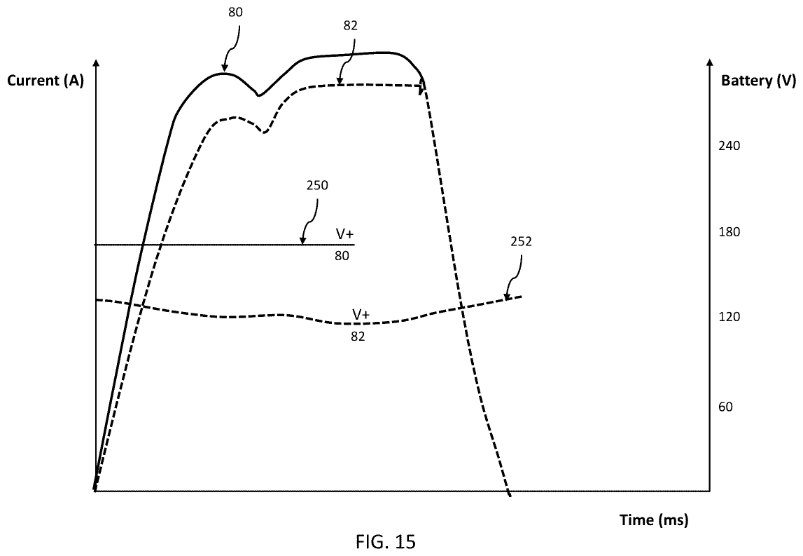

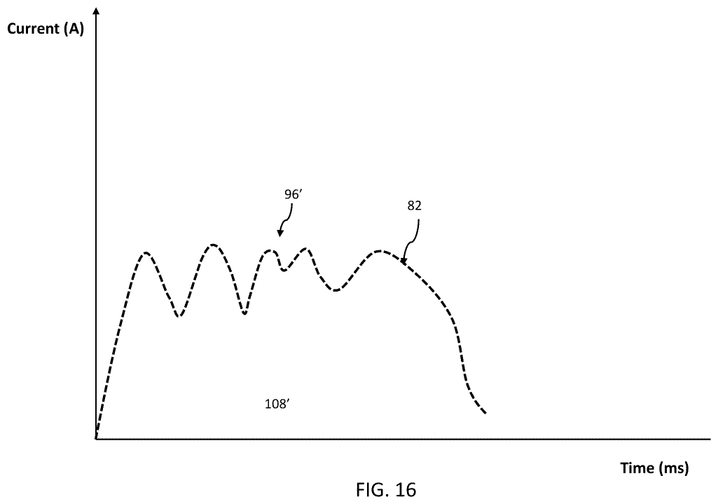

Other circuit breaker 10 anomalies may also be detected and/or measured using the online monitor 62 of the present disclosure. An example of a measured TCCSW 82 is shown in FIG. 15 where the V+ battery voltage 252 is also inferred by the online monitor 62 by measuring the measured TCCSW 82 current. As shown, the V+ battery voltage 250 corresponding to an initial tripping sequence when a reference TCCSW 80 was obtained is substantially higher than the V+ battery voltage measured with the measured TCCSW 82. This may indicate that the battery is not capable of providing sufficient current to the coil 50 to operate the circuit breaker 10 as a result of weak battery cells. Another example is depicted in FIG. 16, which shows the measured TCCSW 82 as a result of loose connections in the control circuit. As shown, the TCCSW 82 includes many peaks and valleys during the plateau 96′ associated with the measured buffer area 108′.

Any directional references used with respect to any of the figures, such as right or left, up or down, or top or bottom, are intended for convenience of description, and do not limit the present disclosure or any of its components to any particular positional or spatial orientation. Additionally, any reference to rotation in a clockwise direction or a counter-clockwise direction is simply illustrative. Any such rotation may be implemented in the reverse direction as that described herein.

Although the foregoing text sets forth a detailed description of embodiments of the disclosure, it should be understood that the legal scope of the invention is defined by the words of the claims set forth at the end of this patent and equivalents. The detailed description is to be construed as exemplary only and does not describe every possible embodiment. Numerous alternative embodiments may be implemented, using either current technology or technology developed after the filing date of this patent, which would still fall within the scope of the claims.

The following additional considerations apply to the foregoing description. Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

In various embodiments, a hardware module may be implemented mechanically or electronically. For example, a hardware module may comprise dedicated circuitry or logic that is permanently configured (e.g., as a special-purpose processor, such as a field programmable gate array (FPGA) or an application-specific integrated circuit (ASIC)) to perform certain operations. A hardware module may also comprise programmable logic or circuitry (e.g., as encompassed within a general-purpose processor or other programmable processor) that is temporarily configured by software to perform certain operations. It will be appreciated that the decision to implement a hardware module mechanically, in dedicated and permanently configured circuitry, or in temporarily configured circuitry (e.g., configured by software) may be driven by cost and time considerations.

Accordingly, the term “hardware module” should be understood to encompass a tangible entity, be that an entity that is physically constructed, permanently configured (e.g., hardwired), or temporarily configured (e.g., programmed) to operate in a certain manner or to perform certain operations described herein. Considering embodiments in which hardware modules are temporarily configured (e.g., programmed), each of the hardware modules need not be configured or instantiated at any one instance in time. For example, where the hardware modules comprise a general-purpose processor configured using software, the general-purpose processor may be configured as respective different hardware modules at different times. Software may accordingly configure a processor, for example, to constitute a particular hardware module at one instance of time and to constitute a different hardware module at a different instance of time.

Hardware modules may provide information to, and receive information from, other hardware modules. Accordingly, the described hardware modules may be regarded as being communicatively coupled. Where multiple of such hardware modules exist contemporaneously, communications may be achieved through signal transmission (e.g., over appropriate circuits and buses) that connect the hardware modules. In embodiments in which multiple hardware modules are configured or instantiated at various times, communications between such hardware modules may be achieved, for example, through the storage and retrieval of information in memory structures to which the multiple hardware modules have access. For example, one hardware module may perform an operation and store the output of that operation in a memory device to which it is communicatively coupled. A further hardware module may then, at a later time, access the memory device to retrieve and process the stored output. Hardware modules may also initiate communications with input or output devices, and may operate on a resource (e.g., a collection of information).

The various operations of example methods described herein may be performed, at least partially, by one or more processors that are temporarily configured (e.g., by software) or permanently configured to perform the relevant operations. Whether temporarily or permanently configured, such processors may constitute processor-implemented modules that operate to perform one or more operations or functions. The modules referred to herein may, in some example embodiments, comprise processor-implemented modules.

Similarly, the methods or routines described herein may be at least partially processor-implemented. For example, at least some of the operations of a method may be performed by one or more processors or processor-implemented hardware modules. The performance of certain of the operations may be distributed among the one or more processors, not only residing within a single machine, but deployed across a number of machines. In some example embodiments, the processor or processors may be located in a single location (e.g., within a home environment, an office environment or as a server farm), while in other embodiments the processors may be distributed across a number of locations.

The performance of certain of the operations may be distributed among the one or more processors, not only residing within a single machine, but deployed across a number of machines. In some example embodiments, the one or more processors or processor-implemented modules may be located in a single device or geographic location (e.g., within a home environment, an office environment, or a server farm). In other example embodiments, the one or more processors or processor-implemented modules may be distributed across a number of devices or geographic locations.

Unless specifically stated otherwise, use herein of words such as “processing,” “computing,” “calculating,” “determining,” “presenting,” “displaying,” or the like may refer to actions or processes of a machine (e.g., a computer) that manipulates or transforms data represented as physical (e.g., electronic, magnetic, or optical) quantities within one or more memories (e.g., volatile memory, non-volatile memory, or a combination thereof), registers, or other machine components that receive, store, transmit, or display information.

As used herein any reference to “one embodiment” or “an embodiment” means that a particular element, feature, structure, or characteristic described in connection with the embodiment is included in at least one embodiment. The appearances of the phrase “in one embodiment” in various places in the specification are not necessarily all referring to the same embodiment.

Some embodiments may be described using the expression “coupled” and “connected” along with their derivatives. For example, some embodiments may be described using the term “coupled” to indicate that two or more elements are in direct physical or electrical contact. The term “coupled,” however, may also mean that two or more elements are not in direct contact with each other, but yet still co-operate or interact with each other. The embodiments are not limited in this context.

Additionally, some embodiments may be described using the expression “communicatively coupled,” which may mean (a) integrated into a single housing, (b) coupled using wires, or (c) coupled wirelessly (i.e., passing data/commands back and forth wirelessly) in various embodiments.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus.

In addition, use of the “a” or “an” are employed to describe elements and components of the embodiments herein. This is done merely for convenience and to give a general sense of the description. This description, and the claims that follow, should be read to include one or at least one and the singular also includes the plural unless it is obvious that it is meant otherwise.

The patent claims at the end of this patent application are not intended to be construed under 35 U.S.C. § 112 (f) unless traditional means-plus-function language is expressly recited, such as “means for” or “step for” language being explicitly recited in the claim(s).

What is claimed is:

1. A method for identifying a fault of a circuit breaker including a trip coil assembly having a coil, the method comprising:
positioning a sensor to measure current flowing through the coil;
providing an online monitor to receive samples of current measured by the sensor;
triggering a first tripping sequence of a circuit breaker known to operate correctly;
sampling, by the online monitor, reference samples from the sensor during the first tripping sequence to generate a reference trip coil current signature waveform (“TCCSW”);
computing a reference sample value for each reference sample;
adding the reference sample values corresponding to a first reference area under the reference TCCSW to determine a first reference area value;
monitoring, by the online monitor, operation of the circuit breaker to detect a second, subsequent tripping sequence;
responding to detection of the second tripping sequence by:
sampling, by the online monitor, measured samples from the sensor during the second tripping sequence to generate a measured TCCSW;
computing a measured sample value for each measured sample;
adding the measured sample values corresponding to a first measured area under the measured TCCSW to determine a first measured area value;
computing a first difference percentage between the first reference area value and the first measured area value; and
generating a first alarm in response to the first difference percentage exceeding at least one first area alarm limit.

2. The method of claim 1, wherein the sensor is a Hall effect sensor.

3. The method of claim 1, wherein the sampling by the online monitor is at a rate of approximately 100,000 Hertz.

4. The method of claim 1, wherein computing reference sample values includes, for each reference sample value, multiplying a current measured during the reference sample by a time period of the reference sample.

5. The method of claim 4, wherein computing measured sample values includes, for each measured sample value, multiplying a current measured during the measured sample by a time period of the measured sample.

6. The method of claim 5, wherein the time period of the reference sample is equal to the time period of the measured sample.

7. The method of claim 1, wherein the first reference area is a reference inrush area beginning when the first tripping sequence is triggered and ending at a first peak of the reference TCCSW and the first measured area is a measured inrush area beginning when the second tripping sequence is detected and ending at a first peak of the measured TCCSW.

8. The method of claim 1, wherein computing a first difference percentage includes computing a difference between the first reference area value and the first measured area value and dividing the difference by the first reference area value.

9. The method of claim 1, further comprising transmitting the first alarm via a transmitter of the online monitor to a remote device.

10. The method of claim 1, further comprising storing each computed reference sample value and each computed measured sample value on a memory of the online monitor.

11. The method of claim 10, further comprising storing the first reference area value and the first measured area value on the memory.

12. The method of claim 1, further comprising:
adding the reference sample values corresponding to a second reference area under the reference TCCSW to determine a second reference area value;
adding the measured sample values corresponding to a second measured area under the measured TCCSW to determine a second measured area value;
computing a second difference percentage between the second reference area value and the second measured area value; and
generating a second alarm in response to the second difference percentage exceeding at least one second area alarm limit.

13. The method of claim 12, wherein the second reference area is a reference latch area beginning at a first peak of the reference TCCSW and ending at a deepest valley of the reference TCCSW, and the second measured area is a measured latch area beginning at a first peak of the measured TCCSW and ending at a deepest valley of the measured TCCSW.

14. The method of claim 13, wherein the deepest valley corresponds to a plunger of the trip coil assembly reaching an end of travel.

15. The method of claim 12, further comprising:
adding the reference sample values corresponding to a third reference area under the reference TCCSW to determine a third reference area value;
adding the measured sample values corresponding to a third measured area under the measured TCCSW to determine a third measured area value;
computing a third difference percentage between the third reference area value and the third measured area value; and
generating a third alarm in response to the third difference percentage exceeding at least one third area alarm limit.

16. The method of claim 15, wherein the third reference area is a reference saturation area beginning at a deepest valley of the reference TCCSW and ending at a plateau of the reference TCCSW, and the third measured area is a measured saturation area beginning at a deepest valley of the measured TCCSW and ending at a plateau of the measured TCCSW.

17. The method of claim 16, wherein the plateau corresponds to the coil being saturated with maximum current.

18. The method of claim 15, further comprising:
adding the reference sample values corresponding to a fourth reference area under the reference TCCSW to determine a fourth reference area value;
adding the measured sample values corresponding to a fourth measured area under the measured TCCSW to determine a fourth measured area value;
computing a fourth difference percentage between the fourth reference area value and the fourth measured area value; and
generating a fourth alarm in response to the fourth difference percentage exceeding at least one fourth area alarm limit.

19. The method of claim 18 wherein the fourth reference area is a reference buffer area beginning at a plateau of the reference TCCSW and ending at a point on the reference TCCSW corresponding to opening of a first auxiliary switch of the circuit breaker, and the fourth measured area is a measured buffer area beginning at a plateau of the measured TCCSW and ending at a point on the measured TCCSW corresponding to the opening of the first auxiliary switch.

20. The method of claim 18, further comprising:
adding the reference sample values corresponding to a fifth reference area under the reference TCCSW to determine a fifth reference area value;
adding the measured sample values corresponding to a fifth measured area under the measured TCCSW to determine a fifth measured area value;
computing a fifth difference percentage between the fifth reference area value and the fifth measured area value; and
generating a fifth alarm in response to the fifth difference percentage exceeding at least one fifth area alarm limit.

21. The method of claim 20, wherein the fifth reference area is a reference discharge area beginning at the point on the reference TCCSW corresponding to opening of a first auxiliary switch and ending when the coil is deenergized, and the fifth measured area is a measured discharge area beginning at the point on the measured TCCSW corresponding to opening of the first auxiliary switch and ending when the coil is deenergized.

22. An online monitor to identify a fault of a circuit breaker including a trip coil assembly having a coil, comprising:
a sensor configured to measure current flowing through the coil;
a processor in operative communication with the sensor to receive samples of current measured by the sensor;
a memory including executable instructions; and
a transmitter;
wherein execution of the executable instructions by the processor causes the processor to:
sample reference samples from the sensor during a first tripping sequence of the circuit breaker when the circuit breaker is known to operate correctly to generate a reference trip coil current signature waveform (“TCCSW”);
compute a reference sample value for each reference sample;
add the reference sample values corresponding to a first reference area under the reference TCCSW to determine a first reference area value;
monitor operation of the circuit breaker to detect a second, subsequent tripping sequence;
respond to detection of the second tripping sequence by:
sampling measured samples from the sensor during the second tripping sequence to generate a measured TCCSW;
computing a measured sample value for each measured sample;
adding the measured sample values corresponding to a first measured area under the measured TCCSW to determine a first measured area value;
compute a first difference percentage between the first reference area value and the first measured area value; and
transmit, via the transmitter to a remote device, a first alarm in response to the first difference percentage exceeding at least one first area alarm limit.

23. The online monitor claim 22, wherein the sensor is a Hall effect sensor.

24. The online monitor of claim 22, wherein the sampling by the online monitor is at a rate of approximately 100,000 Hertz.

25. The online monitor of claim 22, wherein the processor computes the reference sample values by multiplying, for each reference sample value, a current measured during the reference sample by a time period of the reference sample.

26. The online monitor of claim 25, wherein the processor computes the measured sample values by multiplying, for each measured sample value, a current measured during the measured sample by a time period of the measured sample.

27. The online monitor of claim 22, wherein the first reference area is a reference inrush area beginning when the first tripping sequence is triggered and ending at a first peak of the reference TCCSW and the first measured area is a measured inrush area beginning when the second tripping sequence is detected and ending at a first peak of the measured TCCSW.

28. The online monitor of claim 22, wherein the processor computes the first difference percentage by computing a difference between the first reference area value and the first measured area value and dividing the difference by the first reference area value.

29. The online monitor of claim 22, wherein execution of the executable instructions by the processor further causes the processor to store each computed reference sample value and each computed measured sample value on the memory.

30. The online monitor of claim 29, wherein execution of the executable instructions by the processor further causes the processor to store the first reference area value and the first measured area value on the memory.

31. The online monitor of claim 22, wherein execution of the executable instructions by the processor further causes the processor to:
add the reference sample values corresponding to a second reference area under the reference TCCSW to determine a second reference area value;
add the measured sample values corresponding to a second measured area under the measured TCCSW to determine a second measured area value;
compute a second difference percentage between the second reference area value and the second measured area value; and
transmit, via the transmitter, a second alarm in response to the second difference percentage exceeding at least one second area alarm limit.

32. The online monitor of claim 31, wherein the second reference area is a reference latch area beginning at a first peak of the reference TCCSW and ending at a deepest valley of the reference TCCSW, and the second measured area is a measured latch area beginning at a first peak of the measured TCCSW and ending at a deepest valley of the measured TCCSW.

33. The online monitor of claim 32, wherein the deepest valley corresponds to a plunger of the trip coil assembly reaching an end of travel.

34. The online monitor of claim 32, wherein execution of the executable instructions by the processor further causes the processor to:
add the reference sample values corresponding to a third reference area under the reference TCCSW to determine a third reference area value;
add the measured sample values corresponding to a third measured area under the measured TCCSW to determine a third measured area value;
compute a third difference percentage between the third reference area value and the third measured area value; and
transmit, via the transmitter, a third alarm in response to the third difference percentage exceeding at least one third area alarm limit.

35. The online monitor of claim 34, wherein the third reference area is a reference saturation area beginning at a deepest valley of the reference TCCSW and ending at a plateau of the reference TCCSW, and the third measured area is a measured saturation area beginning at a deepest valley of the measured TCCSW and ending at a plateau of the measured TCCSW.

36. The online monitor of claim 35, wherein the plateau corresponds to the coil being saturated with maximum current.

37. The online monitor of claim 35, wherein execution of the executable instructions by the processor further causes the processor to:
add the reference sample values corresponding to a fourth reference area under the reference TCCSW to determine a fourth reference area value;
add the measured sample values corresponding to a fourth measured area under the measured TCCSW to determine a fourth measured area value;
compute a third difference percentage between the fourth reference area value and the fourth measured area value; and
transmit, via the transmitter, a fourth alarm in response to the fourth difference percentage exceeding at least one fourth area alarm limit.

38. The online monitor of claim 37 wherein the fourth reference area is a reference buffer area beginning at a plateau of the reference TCCSW and ending at a point on the reference TCCSW corresponding to opening of a first auxiliary switch of the circuit breaker, and the fourth measured area is a measured buffer area beginning at a plateau of the measured TCCSW and ending at a point on the measured TCCSW corresponding to opening of the first auxiliary switch.

39. The online monitor of claim 38, wherein execution of the executable instructions by the processor further causes the processor to:
add the reference sample values corresponding to a fifth reference area under the reference TCCSW to determine a fifth reference area value;
add the measured sample values corresponding to a fifth measured area under the measured TCCSW to determine a fifth measured area value;
compute a fourth difference percentage between the fifth reference area value and the fifth measured area value; and
transmit, via the transmitter, a fifth alarm in response to the fifth difference percentage exceeding at least one fifth area alarm limit.

40. The online monitor of claim 39, wherein the fifth reference area is a reference discharge area beginning at the point on the reference TCCSW corresponding to the opening of the first auxiliary switch and ending when the coil is deenergized, and the fifth measured area is a measured discharge area beginning at the point on the measured TCCSW corresponding to the opening of the first auxiliary switch and ending when the coil is deenergized.

41. An online monitor to identify a fault of a circuit breaker including a trip coil assembly having a coil, comprising:
a sensor configured to measure current flowing through the coil; and
a processor in operative communication with the sensor to receive samples of current measured by the sensor;
wherein the processor is configured to:
sample reference samples from the sensor during a first tripping sequence of the circuit breaker when the circuit breaker is known to operate correctly to generate a reference trip coil current signature waveform (“TCCSW”);
compute a reference sample value for each reference sample;
add the reference sample values corresponding to a first reference area under the reference TCCSW to determine a first reference area value;
respond to detection of a second, subsequent tripping sequence by:
sampling measured samples from the sensor during the second tripping sequence to generate a measured TCCSW;
computing a measured sample value for each measured sample;
adding the measured sample values corresponding to a first measured area under the measured TCCSW to determine a first measured area value; and
determine whether a first difference percentage between the first reference area value and the first measured area value exceeds at least one first area alarm limit.
